(19) United States
(12) Patent Application Publication
(10) Pub. No.: US 2026/0164635 A1
(43) Pub. Date: Jun. 11, 2026

(54) SEMICONDUCTOR DEVICE AND METHOD FOR FABRICATING THE SAME

(71) Applicant: SAMSUNG ELECTRONICS CO., LTD, Suwon-si (KR)

(72) Inventors: Jong Yong SON, Suwon-si (KR); Ju Youn KIM, Suwon-si (KR); Hyung Jong LEE, Suwon-si (KR); Yoon Young JUNG, Suwon-si (KR); Sang Won JEE, Suwon-si (KR)

(73) Assignee: SAMSUNG ELECTRONICS CO., LTD, Suwon-si (KR)

(21) Appl. No.: 19/259,473

(22) Filed: Jul. 3, 2025

(30) Foreign Application Priority Data
Dec. 11, 2024 (KR) 10-2024-0183334

(51) Int. Cl. H10B 10/00

(52) U.S. Cl. CPC H10B 10/125

(57) ABSTRACT

A semiconductor device includes: a first gate electrode extending in a first direction; a second gate electrode extending in the first direction and spaced apart from the first gate electrode in a second direction that crosses the first direction; a source/drain pattern between the first gate electrode and the second gate electrode; a source/drain contact between the first gate electrode and the second gate electrode, the source/drain contact connected to the source/drain pattern; a node contact connected to the source/drain contact and the first gate electrode; and a node air gap between the first gate electrode and the source/drain contact, wherein the node air gap is not between the second gate electrode and the source/drain contact.

### CROSS-REFERENCE TO RELATED APPLICATION

This application claims priority from Korean Patent Application No. 10-2024-0183334 filed on Dec. 11, 2024 in the Korean Intellectual Property Office, the disclosure of which is incorporated by reference herein in its entirety.

### BACKGROUND

### 1. Technical Field

The disclosure relates to a semiconductor device and a method for fabricating the same.

### 2. Description of Related Art

As one of the scaling techniques for increasing the density of semiconductor devices, multi-gate transistors have been proposed, in which fin-or nanowire-shaped multi-channel active patterns (or silicon bodies) are formed on a substrate, and gates are formed on the surfaces of the multi-channel active patterns.

Since such multi-gate transistors utilize three-dimensional (3D) channels, scaling can be readily achieved. Additionally, the current control capability can be improved without increasing the gate length of the multi-gate transistors. Furthermore, short channel effects (SCE), where the channel region's potential is influenced by the drain voltage, can be effectively suppressed.

As the pitch size of semiconductor devices decreases, further research is required to reduce capacitance and ensure electrical stability between contacts in semiconductor devices.

### SUMMARY

Provided is a semiconductor device that may improve operating characteristics and reliability of a static random-access memory (SRAM) by forming an air gap below a node contact connecting a gate electrode and source/drain regions.

Further, provided is a method for manufacturing a semiconductor device that may improve the operating characteristics and reliability of an SRAM by forming an air gap below a node contact connecting a gate electrode and source/drain regions.

According to an aspect of the disclosure, a semiconductor device may include: a first gate electrode extending in a first direction; a second gate electrode extending in the first direction and spaced apart from the first gate electrode in a second direction that crosses the first direction; a source/drain pattern between the first gate electrode and the second gate electrode; a source/drain contact between the first gate electrode and the second gate electrode, the source/drain contact connected to the source/drain pattern; a node contact connected to the source/drain contact and the first gate electrode; and a node air gap between the first gate electrode and the source/drain contact, wherein the node air gap is not between the second gate electrode and the source/drain contact.

According to an aspect of the disclosure, a semiconductor device may include: a first gate electrode extending in a first direction; a second gate electrode extending in the first direction and spaced apart from the first gate electrode in a second direction that crosses the first direction; a source/drain pattern between the first gate electrode and the second gate electrode; a source/drain contact between the first gate electrode and the second gate electrode, the source/drain contact connected to the source/drain pattern, and including a contact barrier film and a contact filling film, wherein the contact barrier film is between the contact filling film and the source/drain pattern; a node contact connected to the source/drain contact and the first gate electrode, wherein the node contact is in contact with a sidewall of the contact filling film and an upper surface of the contact filling film; and a node air gap between the first gate electrode and the source/drain contact.

According to an aspect of the disclosure, a semiconductor device may include: a first active pattern extending in a first direction; a second active pattern extending in the first direction, wherein the first active pattern and the second active pattern are spaced apart from each other in a second direction that crosses the first direction; a first gate electrode extending in the second direction, wherein the first gate electrode is on the first active pattern and the second active pattern; a second gate electrode extending in the second direction, wherein the second gate electrode is on the first active pattern, and the second gate electrode is spaced apart from the first gate electrode in the first direction; a third gate electrode extending in the second direction, wherein the third gate electrode is on the second active pattern, spaced apart from the first gate electrode in the second direction, and overlaps with the second gate electrode in the second direction; a first source/drain contact between the first gate electrode and the second gate electrode and between the first gate electrode and the third gate electrode; a second source/drain contact spaced apart from the first source/drain contact in the first direction, wherein the second source/drain contact is on the second active pattern; a node contact on the first source/drain contact, wherein the node contact includes a single conductive film structure, and the node contact connects the first source/drain contact and the third gate electrode; and a node air gap between the third gate electrode and the first source/drain contact, wherein the node air gap is not disposed between the first gate electrode and the first source/drain contact.

According to an aspect of the disclosure, a method of manufacturing a semiconductor device may include: providing a first gate electrode extending in a first direction; providing a second gate electrode extending in the first direction and spaced apart from the first gate electrode in a second direction that crosses the first direction; providing a source/drain pattern between the first gate electrode and the second gate electrode; providing a source/drain contact between the first gate electrode and the second gate electrode, the source/drain contact connected to the source/drain pattern; and providing a node contact connected to the source/drain contact and the first gate electrode, wherein the providing the node contact includes providing a node air gap between the first gate electrode and the source/drain contact.

According to an aspect of the disclosure, the node air gap is not between the second gate electrode and the source/drain contact.

According to an aspect of the disclosure, wherein the source/drain contact includes a contact filling film and a contact barrier film, wherein the contact barrier film is between the contact filling film and the source/drain pattern, and the node contact contacts an upper surface of the contact filling film and is on a portion of a sidewall of the contact filling film.

According to an aspect of the disclosure, the node contact contacts the portion of the sidewall of the contact filling film.

Aspects and effects of embodiments of the disclosure are not limited to those mentioned above, and other aspects and effects of embodiments of the disclosure not explicitly stated will be clearly understood by those skilled in the art based on the following description.

### BRIEF DESCRIPTION OF DRAWINGS

The above and other aspects and features of the disclosure will become more apparent by describing in detail example embodiments thereof with reference to the attached drawings, in which:

FIG. 1 is a circuit diagram illustrating a semiconductor device according to some embodiments.

FIG. 2 is an expanded layout diagram of the semiconductor device of FIG. 1.

FIG. 3 is a cross-sectional view taken along a line A-A of FIG. 2.

FIG. 4 is a cross-sectional view taken along a line B-B of FIG. 2.

FIG. 5 is a cross-sectional view taken along a line C-C of FIG. 2.

FIG. 6 is a cross-sectional view taken along a line D-D of FIG. 2.

FIGS. 7 through 10 are enlarged views of a region P of FIG. 3.

FIGS. 11 through 13 are diagrams illustrating a semiconductor device according to some embodiments.

FIGS. 14 through 16 are diagrams illustrating a semiconductor device according to some embodiments.

FIGS. 17 and 18 are diagrams illustrating a semiconductor device according to some embodiments.

FIGS. 19 through 21 are diagrams illustrating a semiconductor device according to some embodiments.

FIGS. 22 and 23 are diagrams illustrating a semiconductor device according to some embodiments.

FIGS. 24 through 34 are diagrams illustrating intermediate steps of a method for manufacturing a semiconductor device according to some embodiments.

### DETAILED DESCRIPTION

Although terms such as “first” and “second” are used to describe various elements or components in the present specification, these elements or components are not limited by these terms. These terms are only used to distinguish a single element or component from other elements or components. Therefore, a first element or component referred to below may be a second element or component within the scope of the disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

In the accompanying drawings of semiconductor devices according to some embodiments, fin field-effect transistors (FinFETs) including fin-shaped channel regions, and transistors including nanowires or nanosheets are illustrated by way of example, but the disclosure is not limited thereto. Embodiments of the disclosure also include planar transistors.

Semiconductor devices according to some embodiments may include tunneling FETs, three-dimensional (3D) transistors, or two-dimensional (2D) material-based transistors (or FETs) and their heterostructures. Further, the semiconductor devices according to some embodiments may include bipolar junction transistors or lateral double-diffused metal-oxide-semiconductor transistors (LDMOSs).

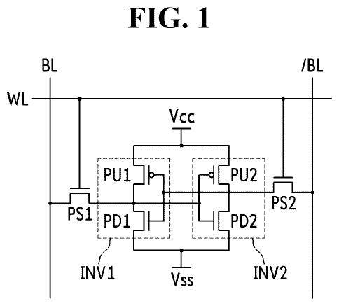

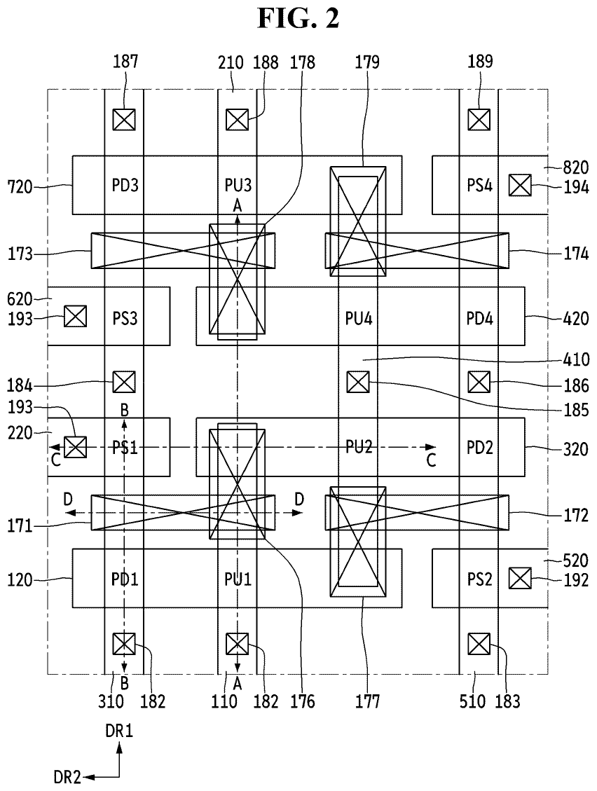

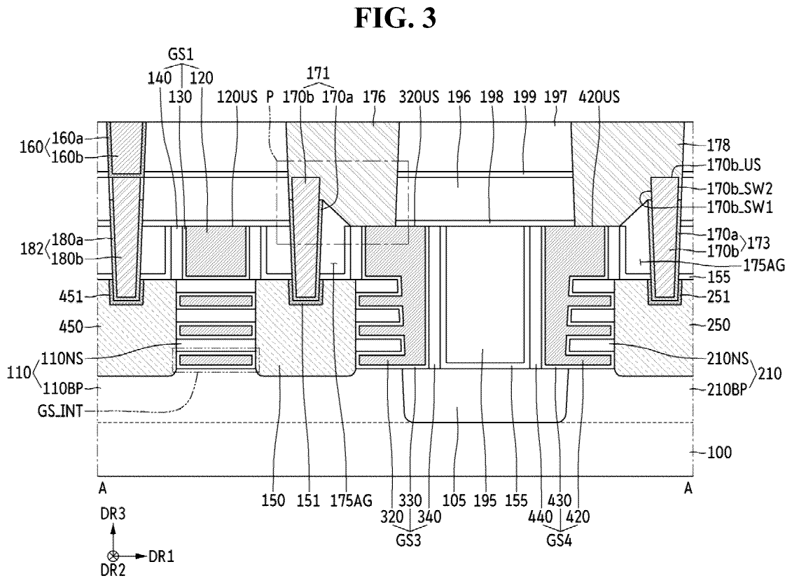

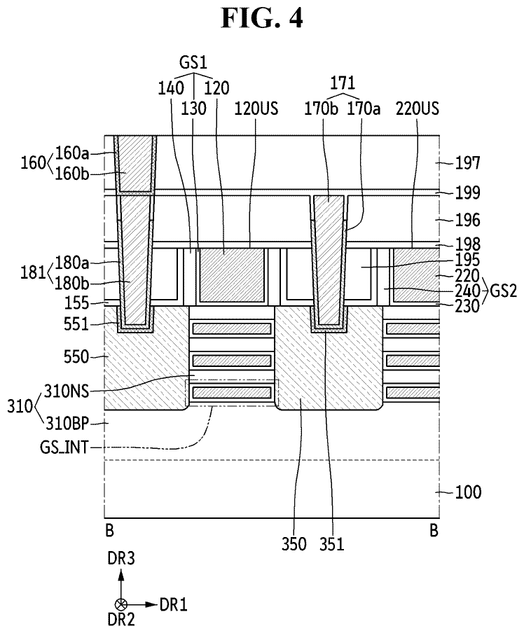

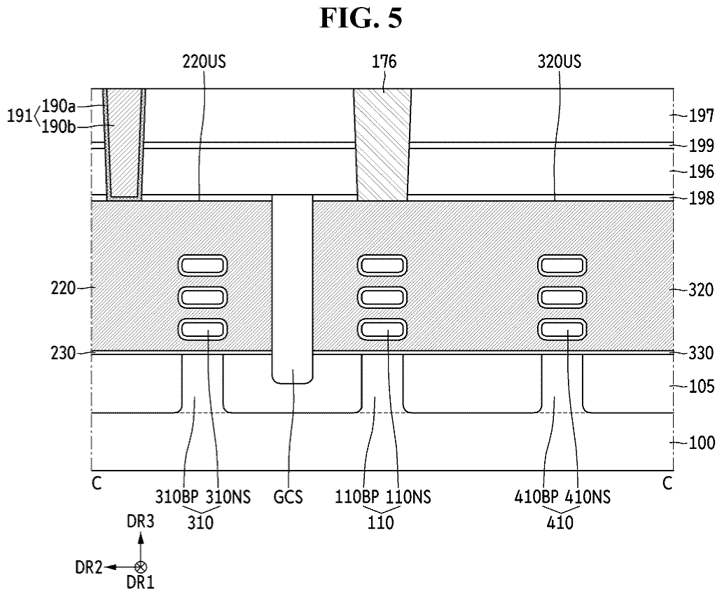

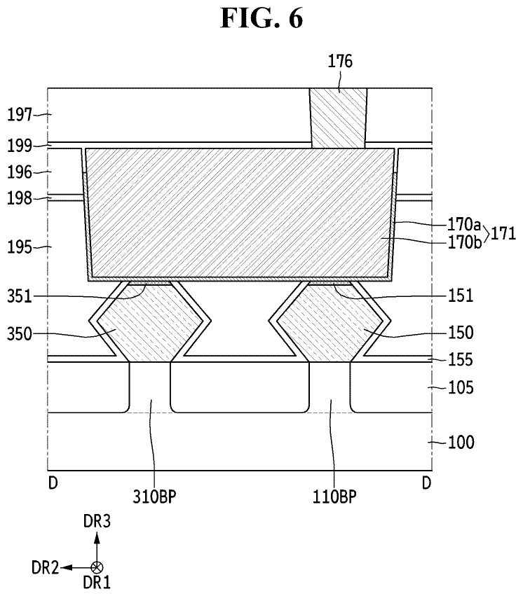

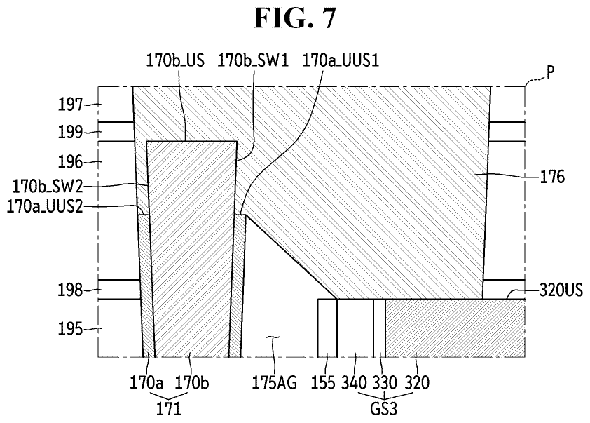

FIG. 1 is a circuit diagram illustrating a semiconductor device according to some embodiments. FIG. 2 is an expanded layout diagram of the semiconductor device of FIG. 1. FIG. 3 is a cross-sectional view taken along a line A-A of FIG. 2. FIG. 4 is a cross-sectional view taken along a line B-B of FIG. 2. FIG. 5 is a cross-sectional view taken along a line C-C of FIG. 2. FIG. 6 is a cross-sectional view taken along a line D-D of FIG. 2. FIGS. 7 through 10 are enlarged views of a region P of FIG. 3.

For reference, FIG. 2 may be an example layout diagram in which a pair of inverters (e.g., a first inverter INV1 and a second inverter INV2) in FIG. 1 are sequentially arranged. Additionally, wiring lines may be included in the back end of line (BEOL).

Referring to FIG. 1, the semiconductor device according to some embodiments may include a first inverter INV1 and a second inverter INV2 connected in parallel between a power supply node Vcc and a ground node Vss, and a first pass transistor PS1 and a second pass transistor PS2 connected to output nodes of the first inverter INV1 and the second inverter INV2, respectively.

The first pass transistor PS1 and the second pass transistor PS2 may be connected to a bitline BL and a complementary bitline /BL, respectively. The gates of the first pass transistor PS1 and the second pass transistor PS2 may be connected to a wordline WL.

The first inverter INV1 may include a first pull-up transistor PU1 and a first pull-down transistor PD1 connected in series between the power supply node Vcc and the ground node Vss. The second inverter INV2 may include a second pull-up transistor PU2 and a second pull-down transistor PD2 connected in series between the power supply node Vcc and the ground node Vss.

The first pull-up transistor PU1 and the second pull-up transistor PU2 may be P-type transistors, and the first pull-down transistor PD1 and the second pull-down transistor PD2 may be N-type transistors.

Further, the first inverter INV1 and the second inverter INV2 may constitute a latch circuit in which the input node of the first inverter INV1 is connected to the output node of the second inverter INV2, and the input node of the second inverter INV2 is connected to the output node of the first inverter INV1.

Referring to FIGS. 2 through 10, the semiconductor device according to some embodiments may include a first active pattern 110, a second active pattern 210, a third active pattern 310, a fourth active pattern 410, a fifth active pattern 510, a first gate electrode 120, a second gate electrode 220, a third gate electrode 320, a fourth gate electrode 420, a fifth gate electrode 520, a sixth gate electrode 620, a seventh gate electrode 720, an eighth gate electrode 820, a first bridge contact 171, a second bridge contact 172, a third bridge contact 173, a fourth bridge contact 174, a first node contact 176, a second node contact 177, a third node contact 178, a fourth node contact 179, a first source/drain contact 181, a second source/drain contact 182, a third source/drain contact 183, a fourth source/drain contact 184, a fifth source/drain contact 185, a sixth source/drain contact 186, a seventh source/drain contact 187, an eighth source/drain contact 188, a ninth source/drain contact 189, a first gate contact 191, a second gate contact 192, a third gate contact 193, and a fourth gate contact 194.

A substrate 100 may be provided and include bulk silicon (Si) or Si-on-insulator (SOI). Alternatively, the substrate 100 may include Si or other materials, such as silicon-germanium (SiGe), SiGe-on-insulator (SGOI), indium antimonide, a lead telluride compound, indium arsenide, indium phosphide, gallium arsenide, or gallium antimonide, but is not limited thereto.

The first, second, third, fourth, and fifth active patterns 110, 210, 310, 410, and 510 may be arranged in a static random-access memory (SRAM). The first, second, and fourth active patterns 110, 210, and 410 may be disposed in a P-type metal-oxide semiconductor (PMOS) region of the SRAM. The third active pattern 310 and the fifth active pattern 510 may be disposed in an N-type metal-oxide semiconductor (NMOS) region of the SRAM.

The first, second, third, fourth, and fifth active patterns 110, 210, 310, 410, and 510 may each extend in a first direction DR1. The first, second, and fourth active patterns 110, 210, and 410 may be disposed between the third active pattern 310 and the fifth active pattern 510 spaced apart in a second direction DR2.

The first active pattern 110 and the second active pattern 210 may be arranged along the first direction DR1. The first active pattern 110 and the second active pattern 210 may be spaced apart from each other in the first direction DR1. The third active pattern 310 may be spaced apart from the first active pattern 110 and the second active pattern 210 in the second direction DR2. The fourth active pattern 410 may be spaced apart from the first active pattern 110 and the second active pattern 210 in the second direction DR2. The fourth active pattern 410 may overlap with portions of the first active pattern 110 and the second active pattern 210 in the second direction DR2. The first, fourth, and second active patterns 110, 410, and 210 may be arranged in a zigzag manner in the first direction DR1. The fourth active pattern 410 may be spaced apart from the fifth active pattern 510 in the second direction DR2.

The first, second, third, and fourth active patterns 110, 210, 310, and 410 may include a first lower pattern 110BP, a second lower pattern 210BP, a third lower pattern 310BP, and a fourth lower pattern 410BP, respectively, and first sheet patterns 110NS, the second sheet patterns 210NS, the third sheet patterns 310NS, and the fourth sheet patterns 410NS, respectively. According to some embodiments, the fifth active pattern 510 may include a fifth lower pattern and fifth sheet patterns.

The first, second, third, and fourth lower patterns 110BP, 210BP, 310BP, and 410BP may each extend longitudinally in the first direction DR1. The first lower pattern 110BP may be spaced apart from the second lower pattern 210BP in the first direction DR1. The first, third, and fourth lower patterns 110BP, 310BP, and 410BP may be spaced apart from each other in the second direction DR2. The first, second, and fourth lower patterns 110BP, 210BP, and 410BP may be disposed between the third lower pattern 310BP and the fifth lower pattern spaced apart in the second direction DR2.

A plurality of first sheet patterns 110NS may be disposed on the first lower pattern 110BP. The first sheet patterns 110NS may be spaced apart from the first lower pattern 110BP in a third direction DR3. The first sheet patterns 110NS may also be spaced apart from each other in the third direction DR3. Four first sheet patterns 110NS are illustrated as being arranged along the third direction DR3, but this is merely for convenience of explanation and is not limiting.

A plurality of second sheet patterns 210NS may be disposed on the second lower pattern 210BP. A plurality of third sheet patterns 310NS may be disposed on the third lower pattern 310BP. A plurality of fourth sheet patterns 410NS may be disposed on the fourth lower pattern 410BP. Descriptions of the second sheet patterns 210NS, the third sheet patterns 310NS, and the fourth sheet patterns 210NS, 310NS, and 410NS may be similar to the description of the first sheet patterns 110NS. According to some embodiments, fifth sheet patterns may also be disposed on the fifth lower pattern.

The third direction DR3 may intersect the first direction DR1 and the second direction DR2. For example, the first direction DR1 and the second direction DR2 may each be perpendicular to the third direction DR3. The first direction DR1 may intersect the second direction DR2. For example, the first direction DR1 may be perpendicular to the second direction DR2.

The first, second, third, and fourth lower patterns 110BP, 210BP, 310BP, and 410BP may be formed by etching portions of the substrate 100, or may include epitaxial layers grown from the substrate 100. The first, second, third, and fourth lower patterns 110BP, 210BP, 310BP, and 410BP may each include an elemental semiconductor such as Si or germanium (Ge). Additionally, the first, second, third, and fourth lower patterns 110BP, 210BP, 310BP, and 410BP may include a compound semiconductor, such as a Group IV-IV compound semiconductor or a Group III-V compound semiconductor. The descriptions of the first, second, third, and fourth lower patterns 110BP, 210BP, 310BP, and 410BP may also apply to the fifth lower pattern included in the fifth active pattern 510.

The Group IV-IV compound semiconductor may include a binary or ternary compound containing at least two from among carbon (C), Si, Ge, and tin (Sn), or a compound obtained by doping the binary or ternary compound with a Group IV element.

The Group III-V compound semiconductor may include a binary, ternary, or quaternary compound obtained by combining at least one Group III element, such as aluminum (Al), gallium (Ga), and indium (In), with at least one Group V element, such as phosphorus (P), arsenic (As), and antimony (Sb).

The first sheet patterns 110NS, the second sheet patterns 210NS, the third sheet patterns 310NS, and the fourth sheet patterns 410NS may each include an elemental semiconductor material such as Si or Ge, a Group IV-IV compound semiconductor, or a Group III-V compound semiconductor. For example, in the case of the first active pattern 110, each of the first sheet patterns 110NS may include the same material as or a different material from the first lower pattern 110BP. The descriptions of the first sheet patterns 110NS, the second sheet patterns 210NS, the third sheet patterns 310NS, and the fourth sheet patterns 410NS may also apply to the fifth sheet patterns included in the fifth active pattern 510.

In the semiconductor device according to some embodiments, the first, second, third, and fourth lower patterns 110BP, 210BP, 310BP, and 410BP may be Si lower fin-shaped patterns, and the first sheet patterns 110NS, the second sheet patterns 210NS, the third sheet patterns 310NS, and the fourth sheet patterns 410NS may be Si sheet patterns.

A field insulating film 105 may be disposed on the substrate 100. The field insulating film 105 may be disposed on the sidewalls of the first, second, third, fourth, and fifth active patterns 110, 210, 310, 410, and 510. For example, the field insulating film 105 may be disposed on the sidewalls of each of the first, second, third, and fourth lower patterns 110BP, 210BP, 310BP, and 410BP.

The field insulating film 105 may not be disposed on the upper surfaces of the first, second, third, and fourth lower patterns 110BP, 210BP, 310BP, and 410BP. The first sheet patterns 110NS, the second sheet patterns 210NS, the third sheet patterns 310NS, and the fourth sheet patterns 410NS may be positioned higher than the upper surface of the field insulating film 105. The field insulating film 105 may be disposed between the first lower pattern 110BP and the second lower pattern 210BP, which are arranged in the first direction DR1.

For example, the field insulating film 105 may completely cover the sidewalls of each of the first, second, third, and fourth lower patterns 110BP, 210BP, 310BP, and 410BP. According to some embodiments, the field insulating film 105 may cover only portions of the sidewalls of each of the first, second, third, and fourth lower patterns 110BP, 210BP, 310BP, and 410BP. In this case, portions of the first, second, third, and fourth lower patterns 110BP, 210BP, 310BP, and 410BP may protrude in the third direction DR3 beyond the upper surface of the field insulating film 105.

The field insulating film 105 may include, for example, an oxide film, a nitride film, an oxynitride film, or a combination thereof. The field insulating film 105 is illustrated as a single layer for convenience of explanation, but the disclosure is not limited thereto.

The first, second, third, fourth, fifth, sixth, seventh, and eighth gate electrodes 120, 220, 320, 420, 520, 620, 720, and 820 may each extend in the second direction DR2. The first gate electrode 120 and the fifth gate electrode 520 may be arranged along the second direction DR2. The first gate electrode 120 and the fifth gate electrode 520 may be spaced apart from each other in the second direction DR2. The second gate electrode 220 and the third gate electrode 320 may be arranged along the second direction DR2. The second gate electrode 220 and the third gate electrode 320 may be spaced apart from each other in the second direction DR2. The fourth gate electrode 420 and the sixth gate electrode 620 may be arranged along the second direction DR2. The fourth gate electrode 420 and the sixth gate electrode 620 may be spaced apart from each other in the second direction DR2. The seventh gate electrode 720 and the eighth gate electrode 820 may be arranged along the second direction DR2. The seventh gate electrode 720 and the eighth gate electrode 820 may be spaced apart from each other in the second direction DR2. The first, third, fourth, and seventh gate electrodes 120, 320, 420, and 720 may be spaced apart from each other in the first direction DR1.

The first, second, sixth, and seventh gate electrodes 120, 220, 620, and 720 may intersect the third active pattern 310. The first gate electrode 120 may intersect the first active pattern 110 and the fourth active pattern 410. The seventh gate electrode 720 may intersect the second active pattern 210 and the fourth active pattern 410. The third, fourth, fifth, and eighth gate electrodes 320, 420, 520, and 820 may intersect the fifth active pattern 510. The third gate electrode 320 may intersect the first active pattern 110 and the fourth active pattern 410. The fourth gate electrode 420 may intersect the second active pattern 210 and the fourth active pattern 410. The first gate electrode 120 and the seventh gate electrode 720 may intersect the terminal end of the fourth active pattern 410. The third gate electrode 320 may intersect the terminal end of the first active pattern 110. The fourth gate electrode 420 may intersect the terminal end of the second active pattern 210.

The first, second, third, fourth, fifth, sixth, seventh, and eighth gate electrodes 120, 220, 320, 420, 520, 620, 720, and 820 may each include, for example, at least one from among a metal, a conductive metal nitride, a conductive metal carbonitride, a conductive metal carbide, a metal silicide, a doped semiconductor material, a conductive metal oxynitride, and a conductive metal oxide. For example, the first, second, third, fourth, fifth, sixth, seventh, and eighth gate electrodes 120, 220, 320, 420, 520, 620, 720, and 820 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel-platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. Here, the conductive metal oxide and conductive metal oxynitride may include oxidized forms of the aforementioned materials but are not limited thereto.

As illustrated, the first pull-up transistor PU1 may be defined by the region where the first gate electrode 120 and the first active pattern 110 intersect, and the first pull-down transistor PD1 may be defined by the region where the first gate electrode 120 and the third active pattern 310 intersect. The first pass transistor PS1 may be defined by the region where the second gate electrode 220 and the third active pattern 310 intersect.

The second pull-up transistor PU2 may be defined by the region where the third gate electrode 320 intersects the fourth active pattern 410, the second pull-down transistor PD2 may be defined by the region where the third gate electrode 320 intersects the fifth active pattern 510, and the second pass transistor PS2 is defined by the region where the fifth gate electrode 520 intersects the fifth active pattern 510.

The third pull-up transistor PU3 may be defined by the region where the seventh gate electrode 720 intersects the second active pattern 210, the third pull-down transistor PD3 may be defined by the region where the seventh gate electrode 720 intersects the third active pattern 310, and the third pass transistor PS3 may be defined by the region where the sixth gate electrode 620 intersects the third active pattern 310.

The fourth pull-up transistor PU4 may be defined by the region where the fourth gate electrode 420 intersects the fourth active pattern 410, the fourth pull-down transistor PD4 may be defined by the region where the fourth gate electrode 420 intersects the fifth active pattern 510, and the fourth pass transistor PS4 may be defined by the region where the eighth gate electrode 820 intersects the fifth active pattern 510.

The first pull-up transistor PU1, the second pull-up transistor PU2, the first pull-down transistor PD1, the second pull-down transistor PD2, the first pass transistor PS1, and the second pass transistor PS2 may be included in a first SRAM cell. The third pull-up transistor PU3, the fourth pull-up transistor PU4, the third pull-down transistor PD3, the pull-down transistor PD4, the third pass transistor PS3, and the fourth pass transistor PS4 may be included in a second SRAM cell.

Each SRAM cell may be connected to a bitline BL and a complementary bitline /BL.

In FIG. 2, a pull-down transistor or a pass transistor is illustrated as being defined at a point where one gate electrode intersects one active pattern, but the disclosure is not limited thereto. A pull-down transistor or a pass transistor may also be defined at a point where one gate electrode intersects a plurality of active patterns.

Each of the first, second, third, and fourth bridge contacts 171, 172, 173, and 174 in FIG. 1 may be a contact that connects the source/drain regions of a pull-up transistor, a pull-down transistor, and a pass transistor. Since the first, second, third, and fourth bridge contacts 171, 172, 173, and 174 are connected to source/drain regions, they may also be referred to as bridge source/drain contacts.

The first bridge contact 171 may be connected to the source/drain region of the first pull-up transistor PU1, the source/drain region of the first pull-down transistor PD1, and the source/drain region of the first pass transistor PS1. The first bridge contact 171 may be disposed between the first gate electrode 120 and the second gate electrode 220, and between the first gate electrode 120 and the third gate electrode 320. The second bridge contact 172 may be connected to the source/drain region of the second pull-up transistor PU2, the source/drain region of the second pull-down transistor PD2, and the source/drain region of the second pass transistor PS2. The second bridge contact 172 may be disposed between the first gate electrode 120 and the third gate electrode 320, and between the third gate electrode 320 and the fifth gate electrode 520. The third bridge contact 173 may be connected to the source/drain region of the third pull-up transistor PU3, the source/drain region of the third pull-down transistor PD3, and the source/drain region of the third pass transistor PS3. The third bridge contact 173 may be disposed between the fourth gate electrode 420 and the seventh gate electrode 720, and between the sixth gate electrode 620 and the seventh gate electrode 720. The fourth bridge contact 174 may be connected to the source/drain region of the fourth pull-up transistor PU4, the source/drain region of the fourth pull-down transistor PD4, and the source/drain region of the fourth pass transistor PS4. The fourth bridge contact 174 may be disposed between the fourth gate electrode 420 and the seventh gate electrode 720, and between the fourth gate electrode 420 and the eighth gate electrode 820.

Each of the first, second, third, and fourth node contacts 176, 177, 178, and 179 in FIG. 1 may be a contact that connects the gate of pull-up and pull-down transistors connected in series between the power supply node Vcc and the ground node Vss to one from among the first, second, third, and fourth bridge contacts 171, 172, 173, and 174.

The first node contact 176 may connect the first bridge contact 171 to the third gate electrode 320. The third gate electrode 320 may be the gate of the second pull-up transistor PU2 and the second pull-down transistor PD2. The second node contact 177 may connect the second bridge contact 172 to the first gate electrode 120. The first gate electrode 120 may be the gate of the first pull-up transistor PU1 and the first pull-down transistor PD1. The third node contact 178 may connect the third bridge contact 173 to the fourth gate electrode 420. The fourth gate electrode 420 may be the gate of the fourth pull-up transistor PU4 and the fourth and pull-down transistor PD4. The fourth node contact 179 may connect the fourth bridge contact 174 to the seventh gate electrode 720. The seventh gate electrode 720 may be the gate of the third pull-up transistor PU3 and the third pull-down transistor PD3.

The first, second, third, fourth, fifth, sixth, seventh, eighth, and ninth source/drain contacts 181, 182, 183, 184, 185, 186, 187, 188, and 189 may be contacts connected to the power supply node Vcc, the ground node Vss, the bitline BL, and the complementary bitline /BL in FIG. 1.

The second, fifth, and eighth source/drain contacts 182, 185, and 188 may be connected to the power supply node Vcc. The first, sixth, and seventh source/drain contacts 181, 186, and 187 may be connected to the ground node Vss. The third, fourth, and ninth source/drain contacts 183, 184, and 189 may be connected to either the bitline BL or the complementary bitline /BL.

The first, second, third, and fourth gate contacts 191, 192, 193, and 194 may be contacts connected to the wordline WL in FIG. 1.

First, second, third, and fourth gate structures GS1, GS2, GS3, and GS4 may each extend longitudinally in the second direction DR2. The first gate structure GS1 and the third gate structure GS3 may be disposed on the first active pattern 110. In other words, the first active pattern 110 may be positioned below the first gate structure GS1 and the third gate structure GS3. The first gate structure GS1 and the third gate structure GS3 may intersect the first active pattern 110. The fourth gate structure GS4 may be disposed on the second active pattern 210. The fourth gate structure GS4 may intersect the second active pattern 210. The second gate structure GS2 may be disposed on the third active pattern 310. The second gate structure GS2 may intersect the third active pattern 310. The fourth active pattern 410 may be disposed below the third gate structure GS3 and may intersect the third gate structure GS3.

The first gate structure GS1 may be spaced apart from the second gate structure GS2 and the third gate structure GS3 in the first direction DR1. The second gate structure GS2 and the third gate structure GS3 may be arranged along the second direction DR2. The second gate structure GS2 may be spaced apart from the third gate structure GS3 in the second direction DR2. The fourth gate structure GS4 may be spaced apart from the third gate structure GS3 in the first direction DR1.

The third gate structure GS3 may be disposed at the terminal end of the first active pattern 110. The third gate structure GS3 may surround the terminal end of the first active pattern 110, which may protrude above the upper surface of the field insulating film 105. For example, an overlap width of the third gate structure GS3 and the first active pattern 110 in the first direction DR1 may be smaller than the width of the third gate structure GS3 in the first direction DR1.

Similarly, the fourth gate structure GS4 may be disposed at the terminal end of the second active pattern 210. The fourth gate structure GS4 may surround the terminal end of the second active pattern 210, which may protrude above the upper surface of the field insulating film 105.

The third gate structure GS3 disposed at the terminal end of the first active pattern 110 may surround the first sheet patterns 110NS disposed near the terminal end of the first lower pattern 110BP. The fourth gate structure GS4 disposed at the terminal end of the second active pattern 210 may surround the second sheet patterns 210NS disposed near the terminal end of the second lower pattern 210BP.

The first, second, third, and fourth gate structures GS1, GS2, GS3, and GS4 may include the first, second, third, and fourth gate electrodes 120, 220, 320, and 420, respectively, first, second, third, and fourth gate insulating films 130, 230, 330, and 430, respectively, and first, second, third, and fourth gate spacers 140, 240, 340, and 440, respectively.

Referring to FIGS. 2 and 3, the first gate structure GS1 may include an inner gate structure GS_INT disposed between the first lower pattern 110BP and the first sheet patterns 110NS, and between adjacent first sheet patterns 110NS in the third direction DR3. The inner gate structure GS_INT may also be disposed between the third lower pattern 310BP and the third sheet patterns 310NS, and between adjacent third sheet patterns 310NS in the third direction DR3. The inner gate structure GS_INT may include the first gate electrode 120 and the first, second, third, and fourth gate insulating films 130, 230, 330, and 430.

The second, third, and fourth gate structures GS2, GS3, and GS4 may also include inner gate structures.

The first, second, third, and fourth gate electrodes 120, 220, 320, and 420 may be disposed on the first, second, third, and fourth gate insulating films 130, 230, 330, and 430, respectively. The first, second, third, and fourth gate insulating films 130, 230, 330, and 430 may be formed along the sidewalls and bottom surfaces of the first, second, third, and fourth gate electrodes 120, 220, 320, and 420.

For example, in the case of the second gate structure GS2, the second gate electrode 220 may be disposed on the third lower pattern 310BP. The second gate electrode 220 may surround the third sheet patterns 310NS in a cross-sectional view. The second gate insulating film 230 may extend along the upper surface of the third lower pattern 310BP and the upper surface of the field insulating film 105. The second gate insulating film 230 may surround the third sheet patterns 310NS in a cross-sectional view. The second gate insulating film 230 is illustrated as a single layer, but this is merely for convenience of explanation and is not limiting. The second gate insulating film 230 may include multiple layers. The second gate insulating film 230 may include an interfacial layer disposed between the third sheet patterns 310NS and the second gate electrode 220, and between the third lower pattern 310BP and the second gate electrode 220, and may further include a high-k insulating film.

The first, second, third, and fourth gate insulating films 130, 230, 330, and 430 may include silicon oxide, silicon-germanium oxide, germanium oxide, silicon oxynitride, silicon nitride, or a high-k material with a dielectric constant greater than a dielectric constant of silicon oxide. The high-k material may include, for example, at least one from among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The semiconductor device according to some embodiments of the disclosure may include a negative capacitance (NC) FET utilizing a negative capacitor. For example, the first, second, third, and fourth gate insulating films 130, 230, 330, and 430 may each include a ferroelectric material film with ferroelectric properties and a paraelectric material film with paraelectric properties.

The ferroelectric material film may have an NC, and the paraelectric material film may have positive capacitance. For example, if two or more capacitors are connected in series, and each of the capacitors has a positive capacitance, the total capacitance of the capacitors is reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a positive capacitance are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include at least one from among hafnium oxide, hafnium zirconium oxide, barium strontium titanium oxide, barium titanium oxide, and lead zirconium titanium oxide. Here, the hafnium zirconium oxide may be, for example, a material obtained by doping hafnium oxide with zirconium (Zr). Alternatively, the hafnium zirconium oxide may be the compound of hafnium (Hf), Zr, and oxygen (O).

The ferroelectric material film may further include a dopant. For example, the dopant may include at least one from among Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of the dopant included in the ferroelectric material film may vary depending on the type of the ferroelectric material included in the ferroelectric material film.

When the ferroelectric material film includes hafnium oxide, the dopant included in the ferroelectric material film may include at least one from among Gd, Si, Zr, Al, and Y.

If the dopant is Al, the ferroelectric material film may contain 3 to 8 atomic % (at %) of Al. Here, the proportion of the dopant may be the ratio of Al to the sum of Hf and Al.

If the dopant is Si, the ferroelectric material film may contain 2 to 10 at % of Si. If the dopant is Y, the ferroelectric material film may contain 2 to 10 at % of Y. If the dopant is Gd, the ferroelectric material film may contain 1 to 7 at % of Gd. If the dopant is Zr, the ferroelectric material film may contain 50 to 80 at % of Zr.

The paraelectric material film may have paraelectric properties. For example, the paraelectric material film may include at least one from among silicon oxide and a high-k metal oxide. The high-k metal oxide may include at least one from among hafnium oxide, zirconium oxide, and aluminum oxide, but the disclosure is not limited thereto.

The ferroelectric material film and the paraelectric material film may include the same material as each other. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be 0.5 to 10 nm, but the disclosure is not limited thereto. Since the critical thickness for exhibiting ferroelectric properties may vary from one ferroelectric material to another, the thickness of the ferroelectric material film may vary depending on its material.

For example, the first, second, third, and fourth gate insulating films 130, 230, 330, and 430 may each include one ferroelectric material film. Alternatively, the first, second, third, and fourth gate insulating films 130, 230, 330, and 430 may each include a plurality of ferroelectric material films that are spaced apart from one another. The first, second, third, and fourth gate insulating films 130, 230, 330, and 430 may each have a layered film structure in which a plurality of ferroelectric material films and a plurality of paraelectric material films are alternately stacked.

The first, second, third, and fourth gate spacers 140, 240, 340, and 440 may be disposed on the sidewalls of the first, second, third, and fourth gate electrodes 120, 220, 320, and 420, respectively.

The first, second, third, and fourth gate spacers 140, 240, 340, and 440 may include, for example, silicon nitride, silicon oxynitride, silicon oxide, silicon carbonitride, silicon boron nitride, silicon oxynitride boron nitride, silicon oxycarbonitride, or a combination thereof. The first, second, third, and fourth gate spacers 140, 240, 340, and 440 are illustrated as single layers, but this is for convenience of explanation and is not limiting.

A gate separation pattern GCS may be disposed between adjacent first, second, third, fourth, fifth, sixth, seventh, and eighth gate electrodes 120, 220, 320, 420, 520, 620, 720, and 820 in the second direction DR2. For example, the gate separation patterns GCS may be disposed between the second gate electrode 220 and the third gate electrode 320. The gate separation pattern GCS may separate the second gate electrode 220 and the third gate electrode 320. The gate separation pattern GCS may be disposed between the second gate electrode 220 and the third gate electrode 320, separating the second gate structure GS2 and the third gate structure GS3.

In FIG. 5, the upper surface of the gate separation pattern GCS is illustrated as being higher than upper surfaces 220US and 320US of the second gate electrode 220 and the third gate electrode 320, but this is not limiting. According to some embodiments, the upper surface of the gate separation pattern GCS may be positioned on the same plane as the upper surfaces 220US and 320US of the second gate electrode 220 and the third gate electrode 320.

Portions of the gate separation pattern GCS are illustrated as being recessed into the field insulating film 105, but this is not limiting. The gate separation pattern GCS may include, for example, at least one from among silicon nitride, silicon oxide, silicon carbonitride, silicon oxycarbonitride, silicon oxynitride, and silicon oxycarbonitride. The gate separation pattern GCS is illustrated as a single layer for convenience, but this is not limiting.

For example, the second gate insulating film 230 and the third gate insulating film 330 may not extend along the sidewalls of the gate separation pattern GCS. In other words, the second gate insulating film 230 and the third gate insulating film 330 may contact the gate separation pattern GCS.

In another example, according to some embodiments, the second gate insulating film 230 and the third gate insulating film 330 may extend along the sidewalls of the gate separation pattern GCS. In other words, the second gate insulating film 230 and the third gate insulating film 330 may not contact the gate separation pattern GCS.

The first source/drain pattern 150 and the fourth source/drain pattern 450 may be disposed on the first active pattern 110. The first source/drain pattern 150 and the fourth source/drain pattern 450 may be disposed on the first lower pattern 110BP. The first source/drain pattern 150 and the fourth source/drain pattern 450 are spaced apart from each other in the first direction DR1. The first source/drain pattern 150 and the fourth source/drain pattern 450 are connected to the first sheet patterns 110NS.

The first source/drain pattern 150 may be disposed on one side of the first gate electrode 120. The fourth source/drain pattern 450 may be disposed on the other side of the first gate electrode 120. The first source/drain pattern 150 may be disposed between the first gate electrode 120 and the third gate electrode 320. The first gate electrode 120 may be disposed between the first source/drain pattern 150 and the fourth source/drain pattern 450.

The second source/drain pattern 250 may be disposed on the second active pattern 210. The second source/drain pattern 250 may be disposed on the second lower pattern 210BP. The second source/drain pattern 250 may be connected to the second sheet patterns 210NS. The second source/drain pattern 250 may be disposed between the fourth gate electrode 420 and the seventh gate electrode 720.

The third source/drain pattern 350 and the fifth source/drain pattern 550 may be disposed on the third active pattern 310. The third source/drain pattern 350 and the fifth source/drain pattern 550 may be disposed on the third lower pattern 310BP. The third source/drain pattern 350 and the fifth source/drain pattern 550 may be spaced apart from each other in the first direction DR1. The third source/drain pattern 350 and the fifth source/drain pattern 550 may be connected to the third sheet patterns 310NS.

The third source/drain pattern 350 may be disposed between the first gate electrode 120 and the second gate electrode 220. The first gate electrode 120 may be disposed between the third source/drain pattern 350 and the fifth source/drain pattern 550.

According to some embodiments, source/drain patterns similar to those described above may be disposed on the first, second, third, fourth, and fifth active patterns 110, 210, 310, 410, and 510 between adjacent first, second, third, fourth, fifth, sixth, seventh, and eighth gate electrodes 120, 220, 320, 420, 520, 620, 720, and 820 in the first direction DR1.

The first, second, third, fourth, and fifth source/drain patterns 150, 250, 350, 450, and 550 may be included in the source/drain regions of transistors. The first, second, third, fourth, and fifth source/drain patterns 150, 250, 350, 450, and 550 may include epitaxial patterns. The first, second, third, fourth, and fifth source/drain patterns 150, 250, 350, 450, and 550 may include semiconductor materials.

The first, second, third, fourth, and fifth source/drain patterns 150, 250, 350, 450, and 550 may include, for example, an elemental semiconductor material such as Si or Ge. Alternatively, the first, second, third, fourth, and fifth source/drain patterns 150, 250, 350, 450, and 550 may include a binary or ternary compound containing at least two from among C, Si, Ge, and Sn, or a compound obtained by doping the binary or ternary compound with a Group IV element.

The first, second, and fourth source/drain patterns 150, 250, and 450, disposed in PMOS region, may include p-type impurities. For example, the p-type impurities may include at least one of boron (B) or Ga. The third source/drain pattern 350 and the fifth source/drain pattern 550, disposed in the NMOS region, may include n-type impurities. For example, the n-type impurities may include at least one from among P, As, Sb, or bismuth (Bi).

In FIG. 3, the first gate insulating film 130 is illustrated as contacting the first source/drain pattern 150 and the fourth source/drain pattern 450, and the fourth gate insulating film 430 is illustrated as contacting the second source/drain pattern 250, but this is not limiting. Contrary to what is illustrated, inner spacers including an insulating material may be disposed between the first gate insulating film 130 and the first source/drain pattern 150 and the fourth source/drain pattern 450, and between the fourth gate insulating film 430 and the second source/drain pattern 250.

In FIG. 4, the first gate insulating film 130 is illustrated as contacting the third source/drain pattern 350 and the fifth source/drain pattern 550, but this is not limiting. According to some embodiments, inner spacers including an insulating material may be disposed between the first gate insulating film 130 and the third source/drain pattern 350 and the fifth source/drain pattern 550.

A source/drain etching stop film 155 may extend along the upper surface of the field insulating film 105 and the sidewalls of the first, second, third, and fourth gate structures GS1, GS2, GS3, and GS4. The source/drain etching stop film 155 may be disposed on the first, second, third, fourth, and fifth source/drain patterns 150, 250, 350, 450, and 550.

The source/drain etching stop film 155 may include a material having an etching selectivity relative to a first interlayer insulating film 195 to be described later. The source/drain etching stop film 155 may include, for example, silicon nitride, silicon oxynitride, silicon oxycarbonitride, silicon boron nitride, silicon oxynitride boron nitride, silicon oxycarbonitride, or a combination thereof.

The first interlayer insulating film 195 may be disposed on the field insulating film 105. For example, the first interlayer insulating film 195 may be disposed on the source/drain etching stop film 155. The upper surface of the first interlayer insulating film 195 may be positioned on the same plane as the upper surfaces 120US, 220US, 320US, and 420US of the first, second, third, and fourth gate electrodes 120, 220, 320, and 420, but this is not limiting.

The first interlayer insulating film 195 may include, for example, at least one from among silicon oxide, silicon nitride, silicon oxynitride, and a low-k material. The dielectric constant of the low-k material may be smaller than the dielectric constant of silicon oxide, which is 3.9. To further lower the dielectric constant of an insulating material, the low-k material may include pores, such as cavities filled with gas or air, in the insulating material. The low-k material may include, for example, fluorinated tetraethyl orthosilicate (FTEOS), hydrogen silsesquioxane (HSQ), methyl silsesquioxane (MQS), carbon-doped silicon oxide (CDO), hydrogen-doped silicon oxide, polyimide nanofoams such as polypropylene oxide, organosilicate glass (OSG), silica aerogel, silica xerogel, mesoporous silica, aromatic polymers, or a combination thereof, but is not limited thereto.

A first etching stop film 198 and a second interlayer insulating film 196 may be sequentially disposed on the first interlayer insulating film 195. The first etching stop film 198 and the second interlayer insulating film 196 may be sequentially disposed on the first, second, third, fourth, fifth, sixth, seventh, and eighth gate electrodes 120, 220, 320, 420, 520, 620, 720, and 820.

The first etching stop film 198 may extend along the upper surface of the first interlayer insulating film 195 and the upper surfaces 120US, 220US, 320US, and 420US of the first, second, third, and fourth gate electrodes 120, 220, 320, and 420.

The first etching stop film 198 may contact the upper surface of the first interlayer insulating film 195. The first etching stop film 198 may contact the upper surfaces 120US, 220US, 320US, and 420US of the first, second, third, and fourth gate electrodes 120, 220, 320, and 420.

The first etching stop film 198 may include, for example, silicon nitride, silicon oxynitride, silicon oxycarbonitride, silicon boron nitride, silicon oxynitride boron nitride, silicon oxycarbonitride, aluminum oxide, aluminum nitride, aluminum oxycarbonitride, or a combination thereof.

The second interlayer insulating film 196 may be disposed on the first etching stop film 198. The second interlayer insulating film 196 may include, for example, at least one from among silicon oxide, silicon nitride, silicon oxynitride, and a low-k material.

A second etching stop film 199 and a third interlayer insulating film 197 may be sequentially disposed on the second interlayer insulating film 196. The second etching stop film 199 may be disposed between the second interlayer insulating film 196 and the third interlayer insulating film 197.

The third interlayer insulating film 197 may include, for example, at least one from among silicon oxide, silicon nitride, silicon oxynitride, and a low-k material. The second etching stop film 199 may include, for example, silicon nitride, silicon oxynitride, silicon oxycarbonitride, silicon boron nitride, silicon oxynitride boron nitride, silicon oxycarbonitride, aluminum oxide, aluminum nitride, aluminum oxycarbonitride, or a combination thereof.

The first bridge contact 171 may be formed across the first active pattern 110 and the third active pattern 310. The first bridge contact 171 may be disposed on the first source/drain pattern 150 and the third first source/drain pattern 350. The first bridge contact 171 may connect the first source/drain pattern 150 and the third first source/drain pattern 350. The first bridge contact 171 may not contact the field insulating film 105.

The third bridge contact 173 may be formed across the second active pattern 210 and the third active pattern 310. The third bridge contact 173 may be disposed on the second source/drain pattern 250.

The first bridge contact 171 and the third bridge contact 173 may be disposed in the first interlayer insulating film 195, the first etching stop film 198, and the second interlayer insulating film 196. The first bridge contact 171 and the third bridge contact 173 may penetrate the first etching stop film 198. Portions of the first bridge contact 171 and the third bridge contact 173 may be disposed in the second interlayer insulating film 196.

The first bridge contact 171 and the third bridge contact 173 may each include a bridge contact barrier film 170a and a bridge contact filling film 170b formed on the bridge contact barrier film 170a. The first bridge contact 171 and the third bridge contact 173 may have a multi-layer structure including different materials from each other. In the first bridge contact 171, the bridge contact barrier film 170a may be disposed between the bridge contact filling film 170b and the first source/drain pattern 150.

The bridge contact barrier film 170a may extend along first sidewall 170b_SW1 and the second sidewall 170b_SW2 and the bottom surface of the bridge contact filling film 170b. In some embodiments, the bridge contact barrier film 170a may not cover portions of the first sidewall 170b_SW1 and the second sidewall 170b_SW2 of the bridge contact filling film 170b. In other words, the bridge contact barrier film 170a may extend along the remaining portions of the first sidewall 170b_SW1 and the second sidewall 170b_SW2 of the bridge contact filling film 170b.

According to some embodiments, each of the second bridge contact 172 and the fourth bridge contact 174 may also include the bridge contact barrier film 170a and the bridge contact filling film 170b.

The first node contact 176 may be disposed on the first bridge contact 171 and the third gate electrode 320. The first node contact 176 may connect the first bridge contact 171 and the third gate electrode 320. The first node contact 176 may connect the third gate electrode 320 and the first source/drain pattern 150. The first node contact 176 may not be connected to the first gate electrode 120. Specifically, the first node contact 176 may be electrically isolated (e.g., electrically insulated) from the first gate electrode 120.

The third node contact 178 may be disposed on the third bridge contact 173 and the fourth gate electrode 420. The third node contact 178 may connect the third bridge contact 173 and the fourth gate electrode 420. The third node contact 178 may connect the fourth gate electrode 420 and the second source/drain pattern 250. According to some embodiments, the third node contact 178 may not be connected to the seventh gate electrode 720.

The first node contact 176 and the third node contact 178 may be disposed in the second interlayer insulating film 196, the third interlayer insulating film 197, the first etching stop film 198, and the second etching stop film 199. The first node contact 176 and the third node contact 178 may penetrate the first etching stop film 198 and the second etching stop film 199.

The bridge contact filling film 170b may include the first sidewall 170b_SW1 and the second sidewall 170b_SW2, which may be opposite to each other in a cross-sectional view along the first direction DR1. For example, in the first bridge contact 171, the first sidewall 170b_SW1 of the bridge contact filling film 170b may face the third gate electrode 320, which may be connected to the first bridge contact 171. The second sidewall 170b_SW2 of the bridge contact filling film 170b may face the first gate electrode 120, which may not be connected to the first bridge contact 171.

The first node contact 176 may contact an upper surface 170b_US of the bridge contact filling film 170b of the first bridge contact 171. For example, in a cross-sectional view, the first node contact 176 may contact the entire upper surface 170b_US of the bridge contact filling film 170b of the first bridge contact 171. The first node contact 176 may cover portions of the first sidewall 170b_SW1 and the second sidewall 170b_SW 2 of the bridge contact filling film 170b.

In some embodiments, the first node contact 176 may contact portions of the first sidewall 170b_SW1 and the second sidewall 170b_SW2 of the bridge contact filling film 170b of the first bridge contact 171. For example, the first node contact 176 may contact the first sidewall 170b_SW1 and the second sidewall 170b_SW2 of the bridge contact filling film 170b of the first bridge contact 171.

The third node contact 178 may contact the upper surface 170b_US of the bridge contact filling film 170b of the third bridge contact 173. The third node contact 178 may cover portions of the first sidewall 170b_SW1 and the second sidewall 170b_SW2 of the bridge contact filling film 170b of the third bridge contact 173. For example, the third node contact 178 may contact portions of the first sidewall 170b_SW1 and the second sidewall 170b_SW2 of the bridge contact filling film 170b of the third bridge contact 173.

The first node contact 176 and the third node contact 178 may have a single-layer structure. The first node contact 176 and the third node contact 178 may not have a multi-layer structure containing different materials from each other. The first node contact 176 and the third node contact 178 may be formed of a single conductive material. In other words, the first node contact 176 and the third node contact 178 may have a single conductive film structure.

The first node contact 176 and the third node contact 178 may include a metal that allows selective growth on a conductive material. The first node contact 176 and the third node contact 178 may include, for example, one from among Ti, W, Mo, Ru, and Co, but are not limited thereto. For example, the first node contact 176 and the third node contact 178 may include W.

According to some embodiments, the second node contact 177 and the fourth node contact 179 may also have a single conductive film structure.

For example, the first node contact 176 is illustrated as extending along the upper surface of the third gate insulating film 330 and the upper surface of the third gate spacer 340, but this is for convenience of explanation and is not limiting.

In FIGS. 7 through 10, in a cross-sectional view, the bridge contact barrier film 170a of the first bridge contact 171 may include a first uppermost surface 170a_UUS1 and a second uppermost surface 170a_UUS2. For example, the first uppermost surface 170a_UUS1 and the second uppermost surface 170a_UUS2 of the bridge contact barrier film 170a may be lower than the upper surface 170b_US of the bridge contact filling film 170b.

The first uppermost surface 170a_UUS1 of the bridge contact barrier film 170a may be connected to the first sidewall 170b_SW1 of the bridge contact filling film 170b. The first uppermost surface 170a_UUS1 of the bridge contact barrier film 170a may be disposed between the bridge contact filling film 170b and the third gate electrode 320. The second uppermost surface 170a_UUS2 of the bridge contact barrier film 170a may be connected to the second sidewall 170b_SW2 of the bridge contact filling film 170b. The second uppermost surface 170a_UUS2 of the bridge contact barrier film 170a may be disposed between the bridge contact filling film 170b and the first gate electrode 120. The first uppermost surface 170a_UUS1 of the bridge contact barrier film 170a may contact the first node contact 176.

In FIG. 7, the second uppermost surface 170a_UUS2 of the bridge contact barrier film 170a may contact the first node contact 176.

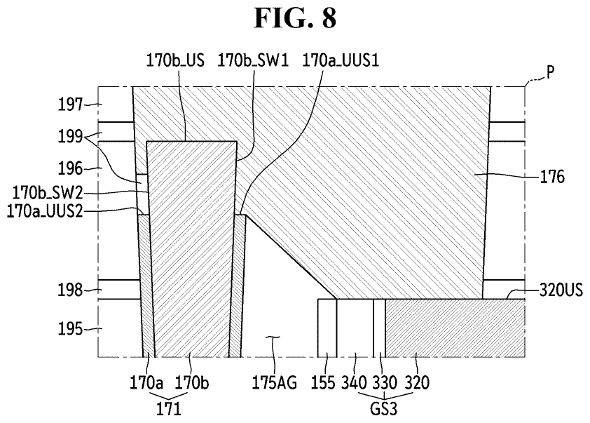

In FIG. 8, the second uppermost surface 170a_UUS2 of the bridge contact barrier film 170a may not contact the first node contact 176. The second uppermost surface 170a_UUS2 of the bridge contact barrier film 170a may contact the second etching stop film 199. During the manufacturing process, a portion of the second etching stop film 199 may fill the space between the bridge contact filling film 170b and the second interlayer insulating film 196, and may contact the second uppermost surface 170a_UUS2 of the bridge contact barrier film 170a. The portion of the second etching stop film 199 that fills the space between the bridge contact filling film 170b and the second interlayer insulating film 196 may remain on the second uppermost surface 170a_UUS2 of the bridge contact barrier film 170a.

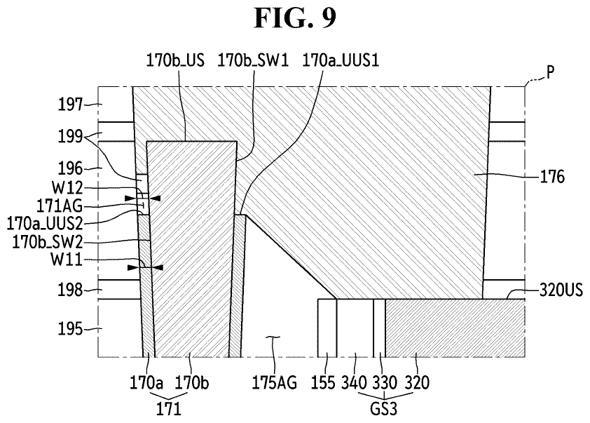

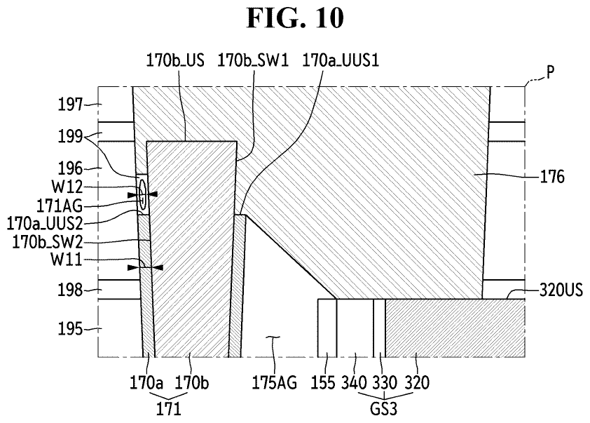

In FIGS. 9 and 10, a contact air gap 171AG may be disposed on the second sidewall 170b_SW2 of the bridge contact filling film 170b. The contact air gap 171AG may be disposed on the second uppermost surface 170a_UUS2 of the bridge contact barrier film 170a. The contact air gap 171AG may be disposed between the bridge contact filling film 170b and the first gate electrode 120.

In FIG. 9, during the manufacturing process, the second etching stop film 199 may not completely fill the space between the bridge contact filling film 170b and the second interlayer insulating film 196. As a result, a contact air gap 171AG may be formed between the second etching stop film 199 and the bridge contact barrier film 170a. On the second uppermost surface 170a_UUS2 of the bridge contact barrier film 170a, a thickness W12 of the contact air gap 171AG in the first direction DR1 may be equal to a thickness W11 of the bridge contact barrier film 170a.

In FIG. 10, during the manufacturing process, while filling the space between the bridge contact filling film 170b and the second interlayer insulating film 196 with a portion of the second etching stop film 199, a contact air gap 171AG may be formed within the second etching stop film 199. On the second uppermost surface 170a_UUS2 of the bridge contact barrier film, the thickness W12 of the contact air gap 171AG in the first direction DR1 may be smaller than the thickness W11 of the bridge contact barrier film 170a.

The content (e.g., relationships between the first bridge contact 171 and the first node contact 176, including the contact air gap 171AG and the node air gap 175AG) described with reference to FIGS. 7 through 10 may also be applied to describe relationships between the third bridge contact 173 and the third node contact 178. Additionally, the content (e.g., relationships between the first bridge contact 171 and the first node contact 176, including the contact air gap 171AG and the node air gap 175AG) described with reference to FIGS. 7 through 10 may also be applied to describe relationships between the second bridge contact 172 and the second node contact 177, and between the fourth bridge contact 174 and the fourth node contact 179.

A node air gap 175AG may be disposed between the third gate electrode 320 and the first bridge contact 171. A node air gap 175AG may be disposed between the fourth gate electrode 320 and the third bridge contact 173. According to some embodiments, a node air gap 175AG may be disposed between the first gate electrode 120 and the second bridge contact 172, and between the seventh gate electrode 720 and the fourth bridge contact 174.

A node air gap 175AG between the third gate electrode 320 and the first bridge contact 171 may be disposed between the first node contact 176 and the first source/drain pattern 150. In a cross-sectional view, the node air gap 175AG between the third gate electrode 320 and the first bridge contact 171 may be surrounded by the first bridge contact 171, the first node contact 176, the third gate structure GS3, and the first source/drain pattern 150. The node air gap 175AG may not be surrounded by the first interlayer insulating film 195. The node air gap 175AG may be directly connected to the bottom surface of the first node contact 176 that faces the first source/drain pattern 150.

A node air gap 175AG between the fourth gate electrode 420 and the third bridge contact 173 may be disposed between the third node contact 178 and the second source/drain pattern 250. In a cross-sectional view, the node air gap 175AG between the fourth gate electrode 420 and the third bridge contact 173 may be surrounded by the third bridge contact 173, the third node contact 178, the fourth gate structure GS4, and the second source/drain pattern 250.

A node air gap 175AG may not be disposed between the first gate electrode 120 and the first bridge contact 171. In other words, a node air gap 175AG may not be disposed between the first bridge contact 171 and the first gate electrode 120, which may not be connected to the first node contact 176. The first interlayer insulating film 195 may fill the space between the first gate electrode 120 and the first bridge contact 171. A node air gap 175AG may be disposed on one side of the first bridge contact 171 and may not be disposed on the other side of the first bridge contact 171.

The node air gap 175AG between the third gate electrode 320 and the first bridge contact 171 may not extend between the first bridge contact 171 and the second gate electrode 220. The first interlayer insulating film 195 may fill the space between the first bridge contact 171 and the second gate electrode 220.

As a node air gap 175AG is disposed between the third gate electrode 320 and the first bridge contact 171, the capacitance between the third gate electrode 320 and the first bridge contact 171 may be reduced. Consequently, signal delays between the third gate electrode 320 and the first bridge contact 171 can be reduced. This can enhance the reliability and performance of the semiconductor device according to some embodiments.

The first source/drain contact 181 may be disposed on the fifth source/drain pattern 550. The first source/drain contact 181 may be connected to the fifth source/drain pattern 550. The second source/drain contact 182 may be disposed on the fourth source/drain pattern 450. The second source/drain contact 182 may be connected to the fourth source/drain pattern 450.

The first source/drain contact 181 and the second source/drain contact 182 may be disposed in the first interlayer insulating film 195, the first etching stop film 198, and the second interlayer insulating film 196. The first source/drain contact 181 and the second source/drain contact 182 may penetrate the first etching stop film 198.

The first source/drain contact 181 and the second source/drain contact 182 may each include a source/drain contact barrier film 180a and a source/drain contact filling film 180b formed on the source/drain contact barrier film 180a. The source/drain contact barrier film 180a may extend along the sidewalls and bottom surface of the source/drain contact filling film 180b. As in the first bridge contact 171 and the third bridge contact 173, the source/drain contact barrier film 180a may partially cover the sidewalls of the source/drain contact filling film 180b.

According to some embodiments, the descriptions for the first source/drain contact 181 and the second source/drain contact 182 may be substantially the same as the descriptions for the third, fourth, fifth, sixth, seventh, eighth, and ninth source/drain contacts 183, 184, 185, 186, 187, 188, and 189.

A first contact silicide film 151 may be disposed between the first source/drain pattern 150 and the first bridge contact 171. A second contact silicide film 251 may be disposed between the second source/drain pattern 250 and the third bridge contact 173. A third contact silicide film 351 may be disposed between the third source/drain pattern 350 and the first bridge contact 171. A fourth contact silicide film 451 may be disposed between the fourth source/drain pattern 450 and the second source/drain contact 182. A fifth contact silicide film 551 may be disposed between the fifth source/drain pattern 550 and the first source/drain contact 181. The first, second, third, fourth, and fifth contact silicide films 151, 251, 351, 451, and 551 may each include a metal silicide material.

The first gate contact 191 may be disposed on the second gate electrode 220. The first gate contact 191 may be connected to the second gate electrode 220. The first gate contact 191 may be disposed in the second interlayer insulating film 196, the third interlayer insulating film 197, the first etching stop film 198, and the second etching stop film 199. The first gate contact 191 may penetrate the first etching stop film 198 and the second etching stop film 199.

The first gate contact 191 may include a gate contact barrier film 190a and a gate contact filling film 190b formed on the gate contact barrier film 190a. The gate contact barrier film 190a may extend along the sidewalls and bottom surface of the gate contact filling film 190b.

According to some embodiments, the descriptions for the second through fourth gate contacts 192, 193, and 194 may be substantially the same as the descriptions for the first gate contact 191.

Source/drain vias 160 may be respectively disposed on the first, second, third, fourth, fifth, sixth, seventh, eighth, and ninth source/drain contacts 181, 182, 183, 184, 185, 186, 187, 188, and 189. The source/drain vias 160 may each be connected to the first, second, third, fourth, fifth, sixth, seventh, eighth, and ninth source/drain contacts 181, 182, 183, 184, 185, 186, 187, 188, and 189. The source/drain vias 160 may be disposed in the third interlayer insulating film 197 and the second etching stop film 199.

The source/drain vias 160 may each include a via barrier film 160a and a via filling film 160b formed on the via barrier film 160a. The via barrier film 160a may extend along the sidewalls and bottom surface of the via filling film 160b.

The bridge contact barrier film 170a, the source/drain contact barrier film 180a, the gate contact barrier film 190a, and the via barrier film 160a may each include, for example, at least one from among Ta, TaN, Ti, TiN, Ru, Co, Ni, NiB, W, WN, tungsten carbonitride (WCN), Zr, zirconium nitride (ZrN), V, vanadium nitride (VN), Nb, NbN, Pt, Ir, Rh, and a 2D material. In some embodiments, the 2D material may be a metallic or semiconducting material. The 2D material may include a 2D allotrope or compound, for example, at least one from among graphene, molybdenum disulfide (MoS₂), molybdenum diselenide (MoSe₂), tungsten diselenide (WSe₂), and tungsten disulfide (WS₂), but is not limited thereto. In other words, the aforementioned 2D materials are provided merely as examples and are not limiting.

The bridge contact filling film 170b, the source/drain contact filling film 180b, the gate contact filling film 190b, and the via filling film 160b may each include, for example, at least one from among Al, W, Co, Ru, Ag, Au, manganese (Mn), and Mo.

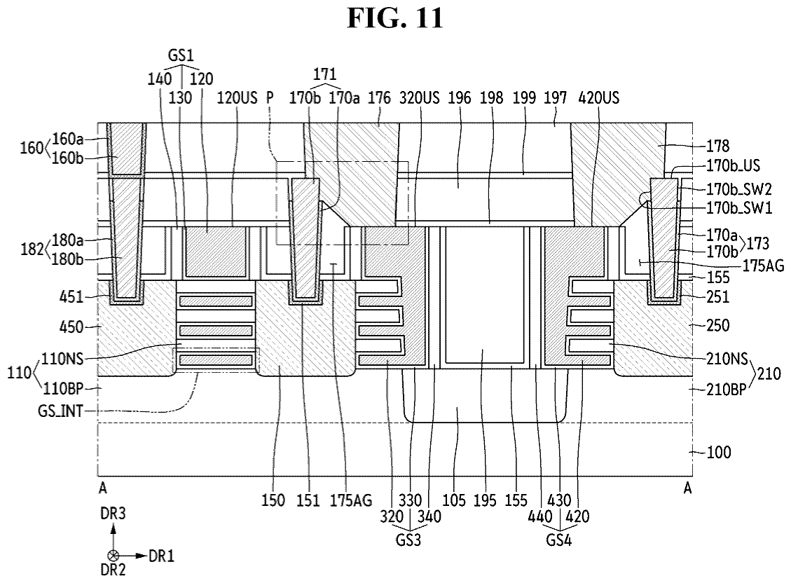

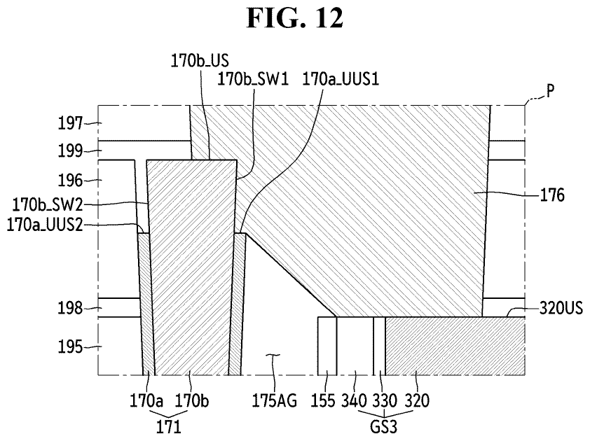

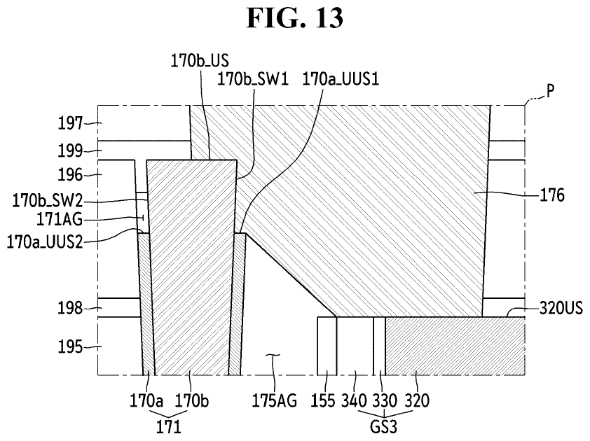

FIGS. 11 through 13 are diagrams illustrating a semiconductor device according to some embodiments. For convenience of explanation, the embodiment of FIGS. 11 through 13 will hereinafter be described, highlighting the differences from the embodiment of FIGS. 1 through 10. For reference, FIG. 11 is a cross-sectional view taken along a line A-A of FIG. 2. FIGS. 12 and 13 are enlarged views of a portion P in FIG. 11.

Referring to FIGS. 11 through 13, in the semiconductor device according to some embodiments, in a cross-sectional view, a first node contact 176 may contact a portion of an upper surface 170b_US of a bridge contact filling film 170b of a first bridge contact 171.

In a cross-sectional view, a third node contact 178 may contact a portion of an upper surface 170b_US of a bridge contact filling film 170b of a third bridge contact 173.

In FIG. 12, a portion of a second etching stop film 199 may fill the entire space between the bridge contact filling film 170b and a second interlayer insulating film 196. A second uppermost surface 170a_UUS2 of a bridge contact barrier film 170a may contact the second etching stop film 199.

In FIG. 13, a contact air gap 171AG may be disposed on a second sidewall 170b_SW2 of the bridge contact filling film 170b. The contact air gap 171AG may be disposed on the second uppermost surface 170a_UUS2 of the bridge contact barrier film 170a. The contact air gap 171AG may be disposed between the second etching stop film 199 and the bridge contact barrier film 170a. According to some embodiments, the contact air gap 171AG may be surrounded by the second etching stop film 199, as illustrated in FIG. 10.

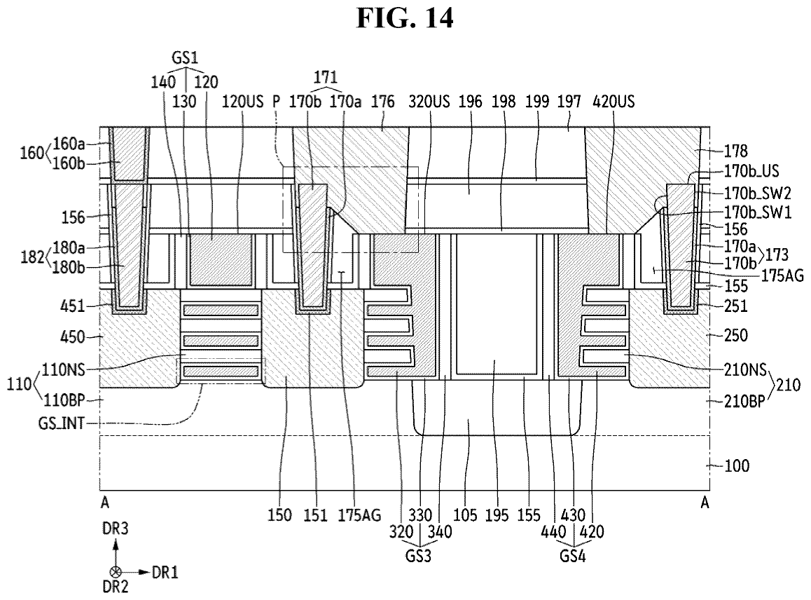

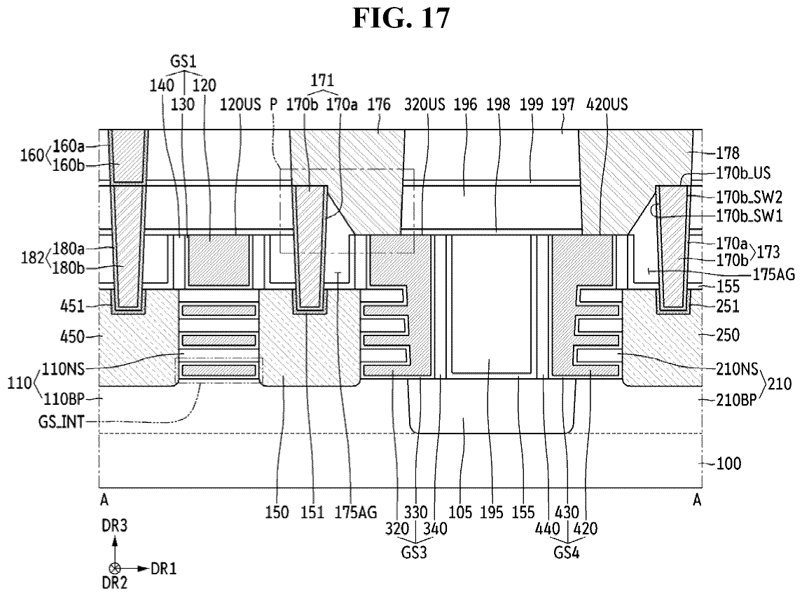

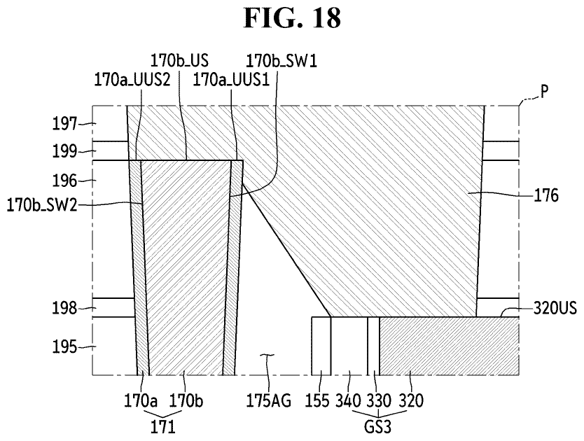

FIGS. 14 through 16 are diagrams illustrating a semiconductor device according to some embodiments. FIGS. 17 and 18 are diagrams illustrating a semiconductor device according to some embodiments. For convenience of explanation, the embodiments of FIGS. 14 through 18 will hereinafter be described, highlighting the differences from the embodiment of FIGS. 1 through 10.

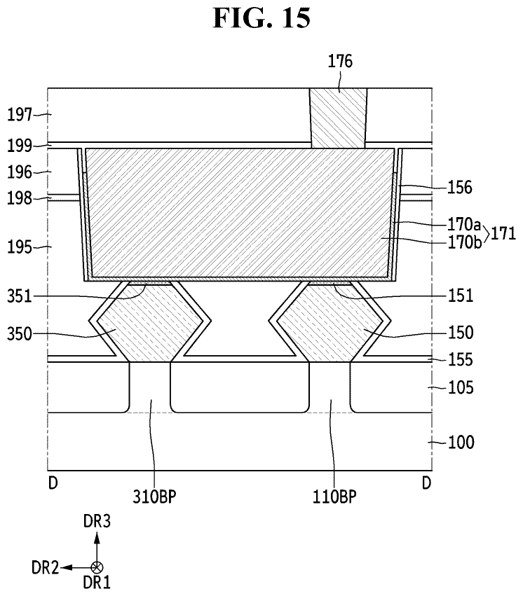

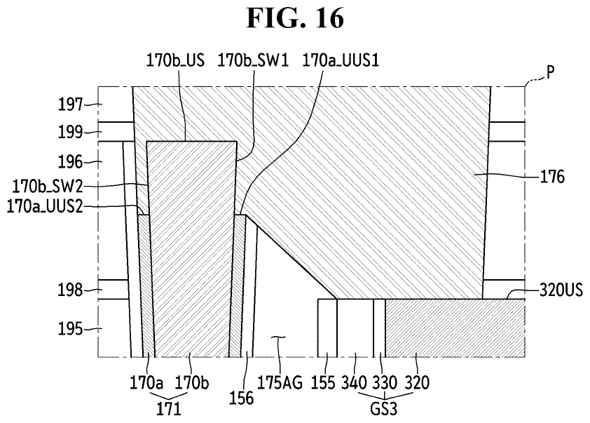

For reference, FIGS. 14 and 17 are cross-sectional views taken along a line A-A of FIG. 2. FIG. 15 is a cross-sectional view taken along a line D-D of FIG. 2. FIGS. 16 and 18 are enlarged views of a portion P in FIGS. 14 and 17.

Referring to FIGS. 14 through 16, the semiconductor device according to some embodiments may further include a contact liner 156 disposed on the sidewalls of a first bridge contact 171 and a third bridge contact 173.

The contact liner 156 may be disposed on the sidewalls of a second source/drain contact 182. The contact liner 156 may extend to the upper surface of a second interlayer insulating film 196 but is not limited thereto.

The contact liner 156 may include an insulating material. The contact liner 156 may include silicon oxycarbide but is not limited thereto.

Referring to FIGS. 17 and 18, in the semiconductor device according to some embodiments, a bridge contact barrier film 170a may extend along an entirety of the first sidewall 170b_SW1 and along the second sidewall 170b_SW2 of a bridge contact filling film 170b.

A bridge contact barrier film 170a may cover the entire first sidewall 170b_SW1 and the second sidewall 170b_SW2 of the bridge contact filling film 170b. The bridge contact barrier film 170a may extend to an upper surface 170b_US of the bridge contact filling film 170b. For example, a first uppermost surface 170a_UUS1 and a second uppermost surface 170a_UUS2 of the bridge contact barrier film 170a may lie on the same plane as the upper surface 170b_US of the bridge contact filling film 170b.

A first node contact 176 may not contact the first sidewall 170b_SW1 and the second sidewall 170b_SW2 of the bridge contact filling film 170b of the first bridge contact 171. A third node contact 178 may not contact the first sidewall 170b_SW1 and the second sidewall 170b_SW2 of the bridge contact filling film 170b of the third bridge contact 173.

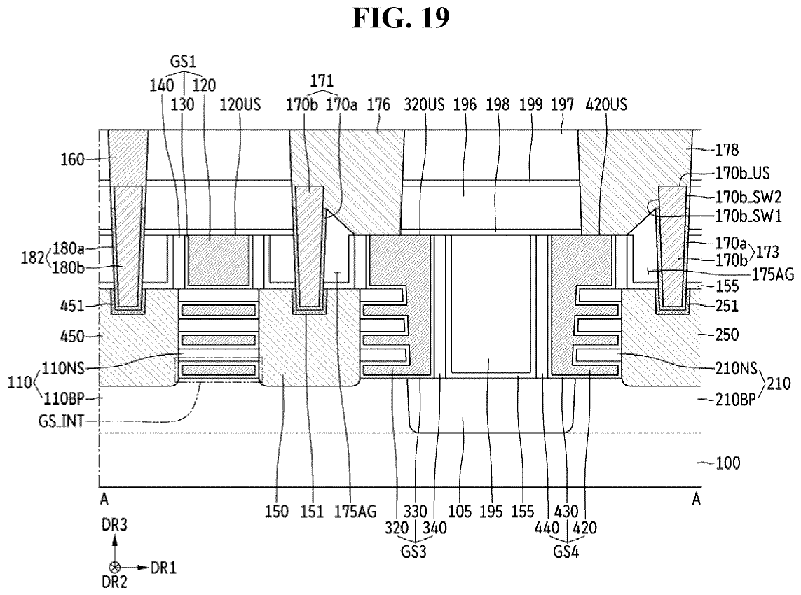

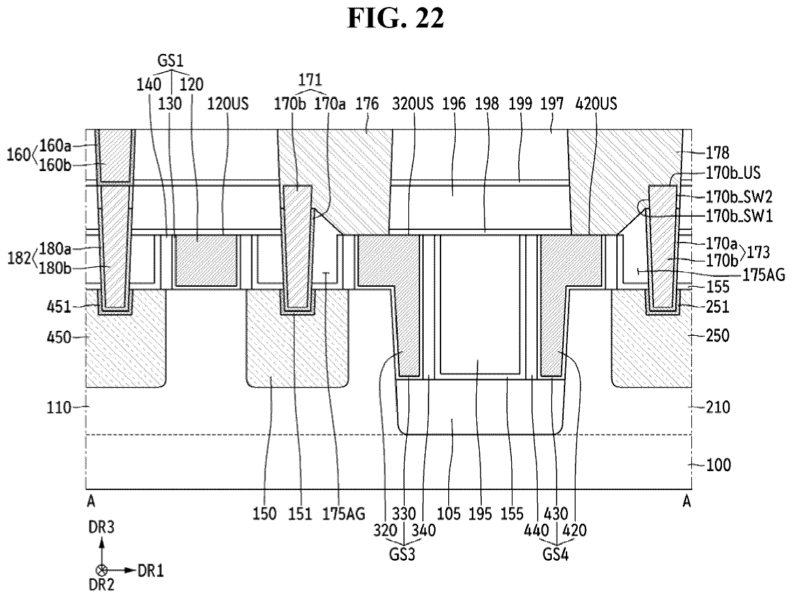

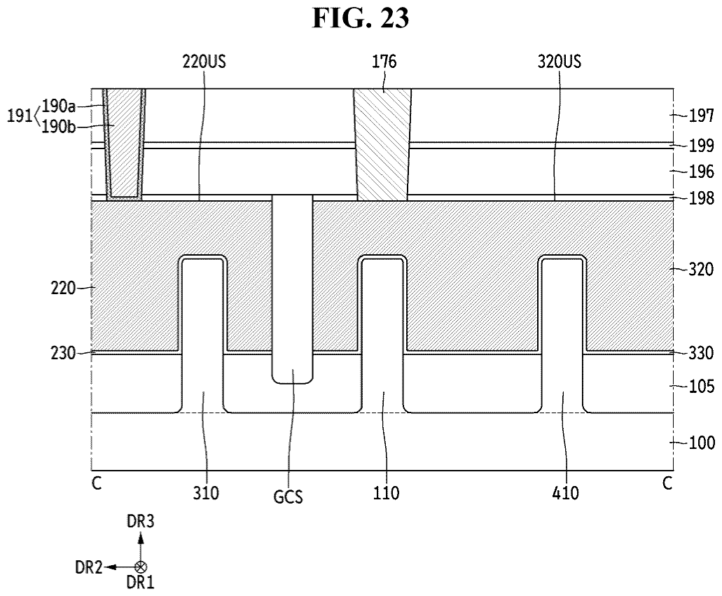

FIGS. 19 through 21 are diagrams illustrating a semiconductor device according to some embodiments. FIGS. 22 and 23 are diagrams illustrating a semiconductor device according to some embodiments. For convenience of explanation, the embodiments of FIGS. 19 through 23 will hereinafter be described, highlighting the differences from the embodiment of FIGS. 1 through 10.

Referring to FIG. 19, in the semiconductor device according to some embodiments, a source/drain via 160 may have a single conductive film structure.

The source/drain via 160 may not include a via barrier film (e.g., the via barrier film 160a in FIG. 3).

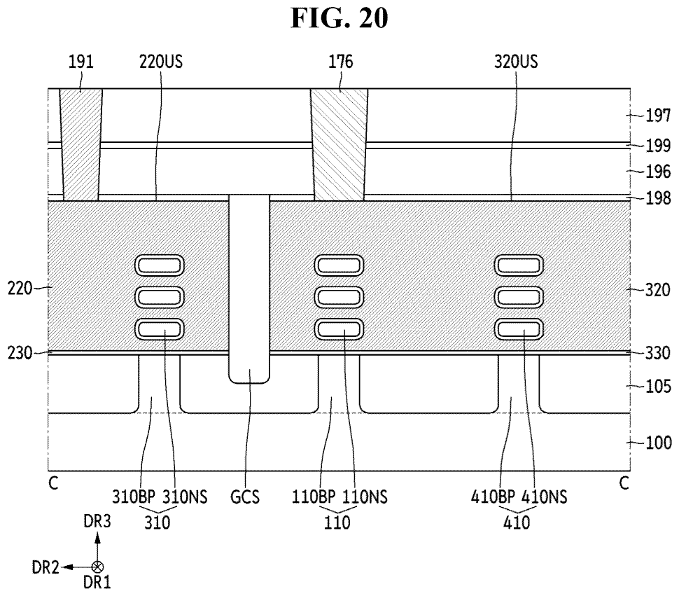

Referring to FIG. 20, in the semiconductor device according to some embodiments, a first gate contact 191 may have a single conductive film structure.

The first gate contact 191 may not include a gate contact barrier film (e.g.,. the gate contact barrier film 190a in FIG. 4). According to some embodiments, the second, third, and fourth gate contacts 192, 193, and 194 (see FIG. 2) may also have a single conductive film structure.

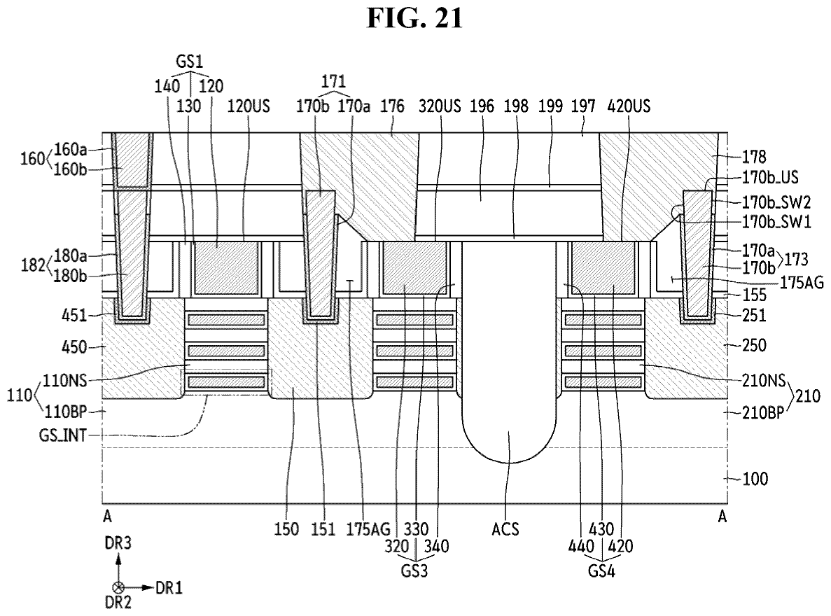

Referring to FIG. 21, in the semiconductor device according to some embodiments, a first active pattern 110 and a second active pattern 210 may be separated by an active pattern separation structure ACS.

The active pattern separation structure ACS may be disposed between a third gate structure GS3 and a fourth gate structure GS4. The upper surface of the active pattern separation structure ACS is illustrated as lying on the same plane as upper surfaces 320US and 420US of the third gate electrode 320 and the fourth gate electrode 420, but this is not limiting. According to some embodiments, the upper surface of the active pattern separation structure ACS may be higher than the upper surfaces 320US and 420US of the third gate electrode 320 and the fourth gate electrode 420.

The active pattern separation structure ACS may include, for example, at least one from among silicon nitride, silicon oxide, silicon carbonitride, silicon oxycarbonitride, silicon oxynitride, and silicon oxycarbonitride. The active pattern separation structure ACS is illustrated as a single layer for convenience but is not limited thereto.

Referring to FIGS. 22 and 23, in the semiconductor device according to some embodiments, a first active pattern 110 may not include first sheet patterns NS1.

Second, third, and fourth active patterns 210, 310, and 410 may not include second sheet patterns 210NS, third sheet patterns 310NS, and fourth sheet patterns 410NS.

A first gate structure GS1, a third gate structure GS3, and a fourth gate structure GS4 may not include an inner gate structure GS_INT. According to some embodiments, a second gate structure (e.g., the second gate structure GS2 in FIG. 4) may also not include an inner gate structure GS_INT.

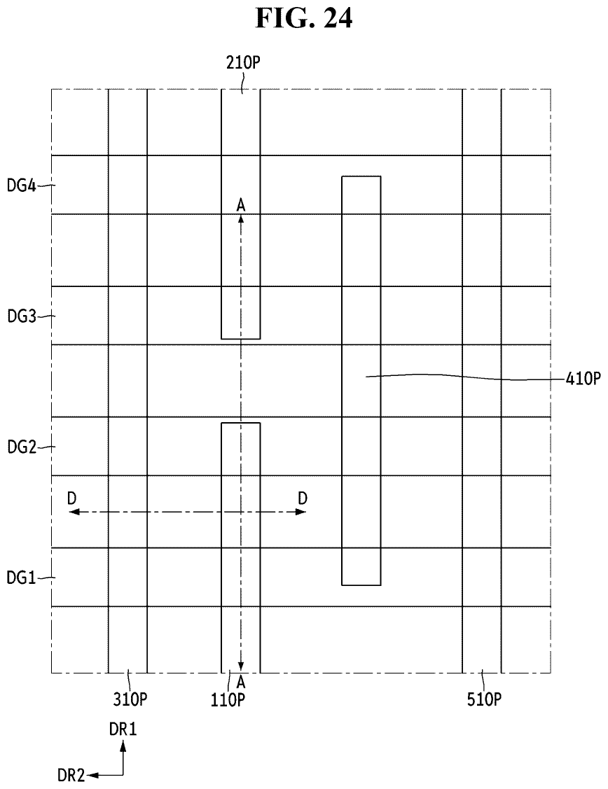

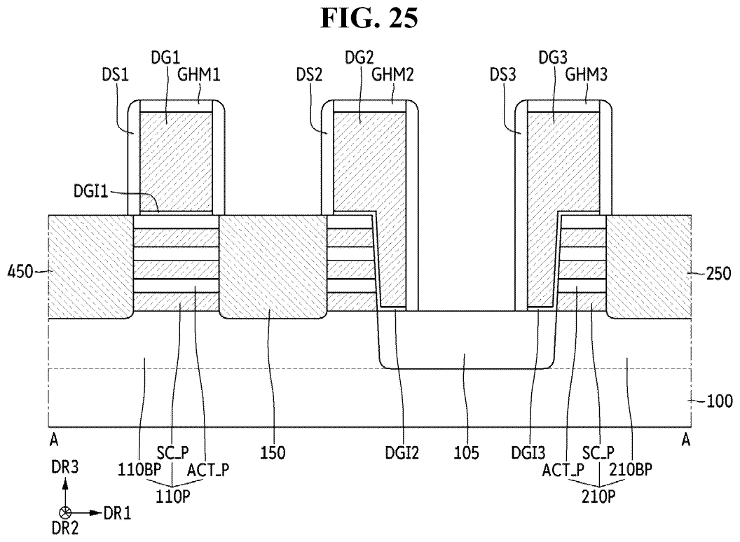

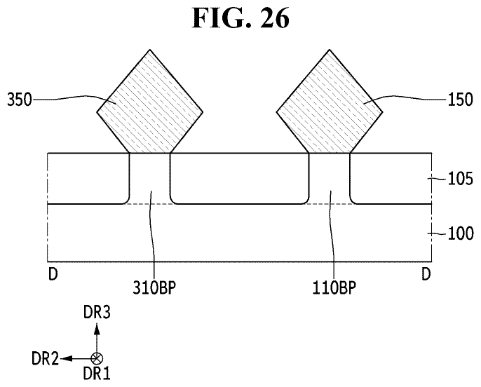

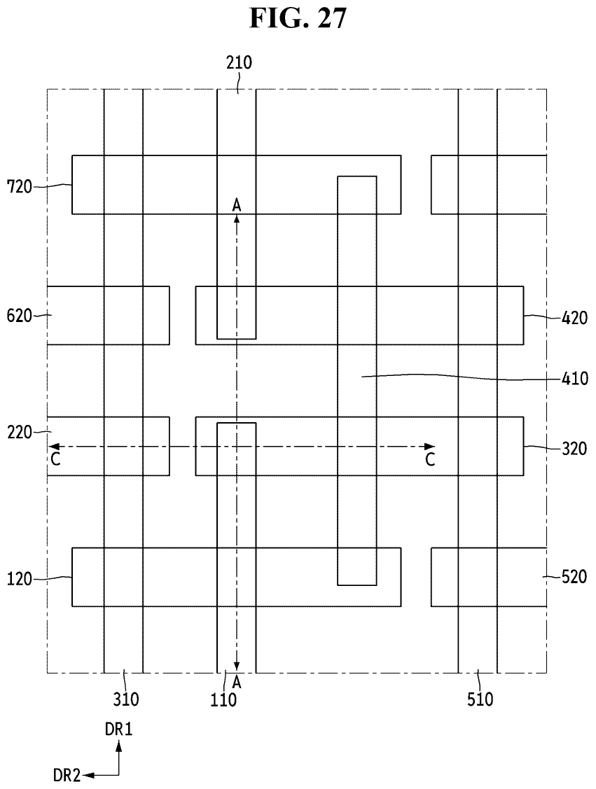

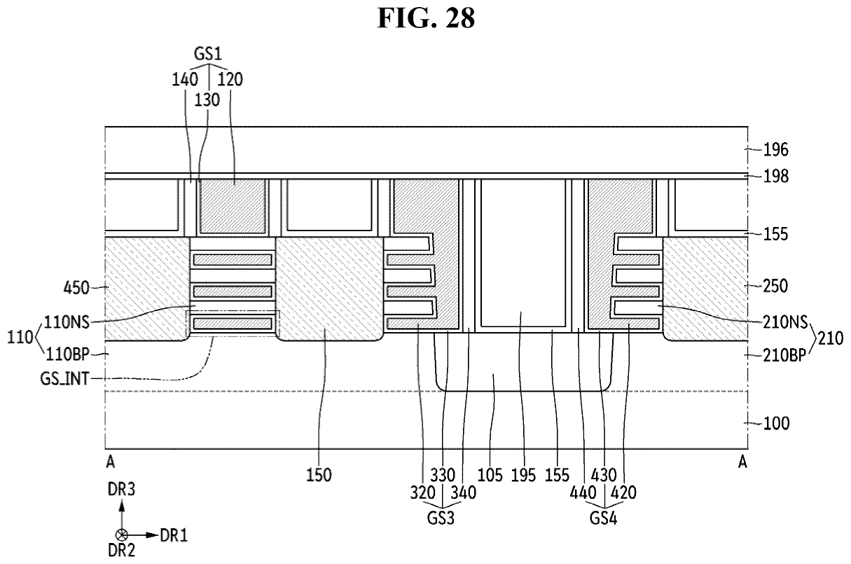

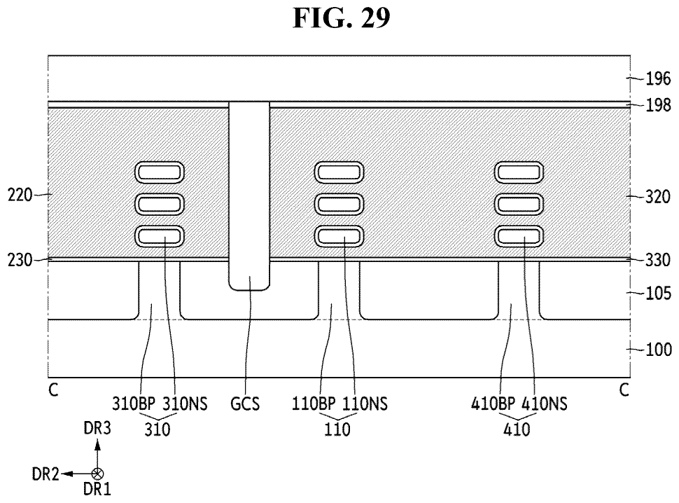

FIGS. 24 through 34 are diagrams illustrating intermediate steps of a method for manufacturing a semiconductor device according to some embodiments. For reference, FIGS. 24 and 27 may be layout diagrams.

Referring to FIGS. 19 through 21, first, second, third, and fourth dummy gate electrodes DG1, DG2, DG3, and DG4 may be formed on first, second, third, fourth, and fifth pre-active patterns 110P, 210P, 310P, 410P, and 510P on a substrate 100.

The first pre-active pattern 110P may include a first lower pattern 110BP, and active patterns ACT_P and sacrificial patterns SC_P that are alternately formed on the first lower pattern 110BP. The second pre-active pattern 210P may include a second lower pattern 210BP, and active patterns ACT_P and sacrificial patterns SC_P that are alternately formed on the second lower pattern 210BP. According to some embodiments, each of third, fourth, and fifth pre-active patterns 310P, 410P, and 510P may also include active patterns ACT_P and sacrificial patterns SC_P that are alternately formed. For example, the active patterns ACT_P may each include an Si film, and the sacrificial patterns SC_P may each include an SiGe film.

The first, second, third, and fourth dummy gate electrodes DG1, DG2, DG3, and DG4 may each extend longitudinally in a second direction DR2. The first, second, third, and fourth dummy gate electrodes DG1, DG2, DG3, and DG4 may be spaced apart in a first direction DR1.

The first dummy gate electrode DG1 and the second gate electrode DG2 may intersect the first, third, fourth, and fifth pre-active patterns 110P, 310P, 410P, and 510P. The third dummy gate electrode DG3 and the fourth dummy gate electrode DG4 may intersect the second, third, fourth, and fifth pre-active patterns 210P, 310P, 410P, and 510P.

For example, a first gate hard mask GHM1 may be formed on the upper surface of the first dummy gate electrode DG1. A first dummy gate insulating film DGI1 may be disposed on the bottom surface of the first dummy gate electrode DG1. A first dummy spacer DS1 may be disposed on the sidewalls of the first dummy gate electrode DG1. A second gate hard mask GHM2 may be formed on the upper surface of the second dummy gate electrode DG2. A second dummy gate insulating film DGI2 may be disposed on the bottom surface of the second dummy gate electrode DG2. A second dummy spacer DS2 may be disposed on the sidewalls of the second dummy gate electrode DG2. A third gate hard mask GHM3 may be formed on the upper surface of the third dummy gate electrode DG3. A third dummy gate insulating film DGI3 may be disposed on the bottom surface of the third dummy gate electrode DG3. A third dummy spacer DS3 may be disposed on the sidewalls of the third dummy gate electrode DG3.

Source/drain patterns may be formed on the first, second, third, and fourth pre-active patterns 110P, 210P, 310P, 410P, and 510P between adjacent first, second, third, and fourth dummy gate electrodes DG1, DG2, DG3, and DG4 in the first direction DR1.

For example, a first source/drain pattern 150 and a fourth source/drain pattern 450 may be formed on the first pre-active pattern 110P. A second source/drain pattern 250 may be formed on the second pre-active pattern 210P, and a third source/drain pattern 350 may be formed on the third pre-active pattern 310P.

Referring to FIGS. 27 through 29, a source/drain etching stop film 155 and a first interlayer insulating film 195 may be formed on the first, second, and fourth source/drain patterns 150, 250, and 450.

While forming the source/drain etching stop film 155 and the first interlayer insulating film 195, the first, second, and third gate hard masks GHM1, GHM2, and GHM3 may be removed.

Thereafter, the first, second, third, and fourth dummy gate electrodes DG1, DG2, DG3, and DG4 and the first, second, and third dummy gate insulating films DGI1, DGI2, and DGI3 may be removed. The sacrificial patterns SC_P in each of the first pre-active pattern 110P and the second pre-active pattern 210P may be removed, forming a first active pattern 110 and a second active pattern 210. The active patterns ACT_P in the first pre-active pattern 110P may become first sheet patterns 110NS. The active patterns ACP_P in the second pre-active pattern 210P may become second sheet patterns 210NS. In this manner, third, fourth, and fifth active patterns 310, 410, and 510 may be formed.

Thereafter, metal gate electrodes may be formed in the spaces left by the removed first, second, third, and fourth dummy gate electrodes DG1, DG2, DG3, and DG4 through a replacement metal gate (RMG) process.

Thereafter, through a gate separation process that separates the metal gate electrodes, first, second, third, fourth, fifth, sixth, seventh, and eighth gate electrodes 120, 220, 320, 420, 520, 620, 720, and 820 may be formed on the substrate 100. The first interlayer insulating film 195 may be disposed on the sidewalls of each of the first, second, third, fourth, fifth, sixth, seventh, and eighth gate electrodes 120, 220, 320, 420, 520, 620, 720, and 820.

For example, the first gate electrode 120 may be formed on the first, third, and fourth active patterns 110, 310, and 410. The second gate electrode 220 may be formed on the third active pattern 310. The third gate electrode 320 may be formed on the first, fourth, and fifth active patterns 110, 410, and 510. The fourth gate electrode 420 may be formed on the second, fourth, and fifth active patterns 210, 410, and 510.

Thereafter, a first etching stop film 198 and a second interlayer insulating film 196 may be sequentially formed on the first, second, third, and fourth gate electrodes 120, 220, 320, and 420.

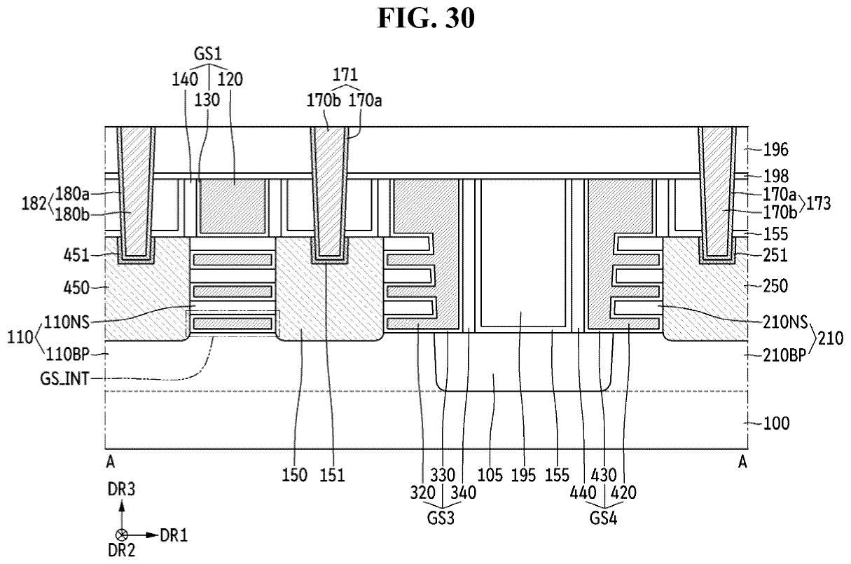

Referring to FIG. 30, a first bridge contact 171, a third bridge contact 173, and a second source/drain contact 182 may be formed in the first interlayer insulating film 195, the second interlayer insulating film 196, and the first etching stop film 198.

The first bridge contact 171 may be formed on the first source/drain pattern 150. The third bridge contact 173 may be formed on the second source/drain pattern 250. The second source/drain contact 182 may be formed on the fourth source/drain pattern 450.

The first bridge contact 171 and the third bridge contact 173 may each include a bridge contact barrier film 170a and a bridge contact filling film 170b. The second source/drain contact 182 may include a source/drain contact barrier film 180a and a source/drain contact filling film 180b.

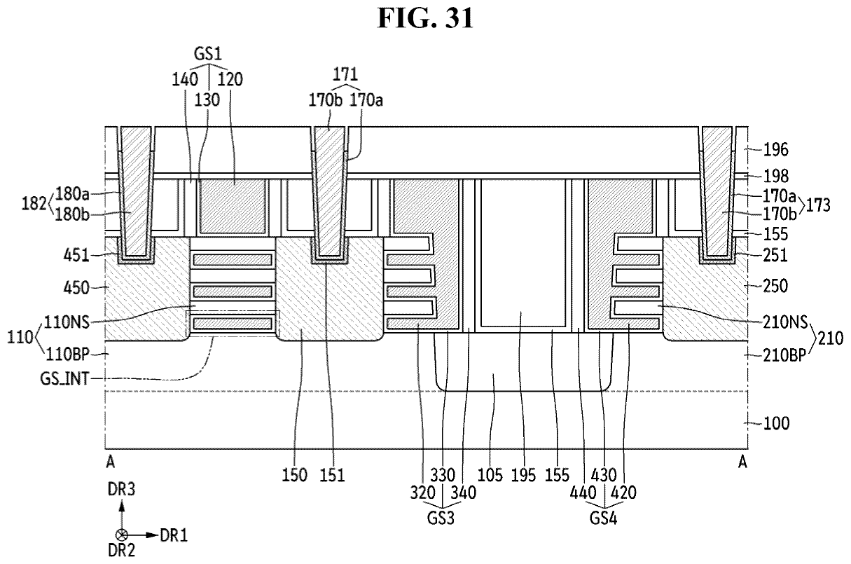

Referring to FIG. 31, portions of the bridge contact barrier film 170a of the first bridge contact 171 may be removed, exposing portions of the sidewalls of the bridge contact filling film 170b of the first bridge contact 171.

Portions of the bridge contact barrier film 170a of the third bridge contact 173 may be removed, exposing portions of the sidewalls of the bridge contact filling film 170b of the third bridge contact 173. Portions of the source/drain contact barrier film 180a of the second source/drain contact 182 may be removed, exposing portions of the sidewalls of the source/drain contact filling film 180b of the second source/drain contact 182.

A bridge contact recess may be formed between the second interlayer insulating film 196 and the bridge contact filling film 170b. A source/drain contact recess may be formed between the second interlayer insulating film 196 and the source/drain contact filling film 180b.

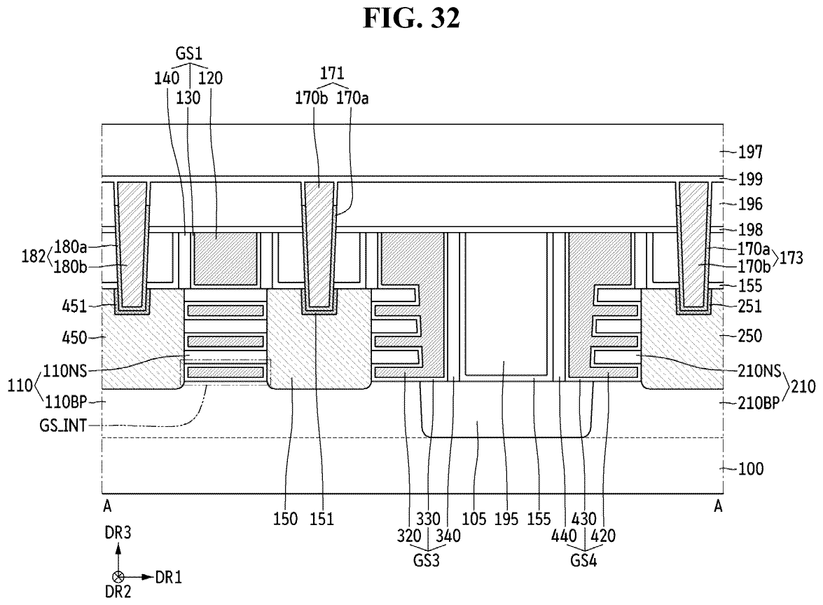

Referring to FIGS. 31 and 32, a second etching stop film 199 and a third interlayer insulating film 197 may be sequentially formed on the first bridge contact 171, the third bridge contact 173, and the second source/drain contact 182.

The second etching stop film 199 may fill at least a portion of the bridge contact recess formed between the second interlayer insulating film 196 and the bridge contact filling film 170b. The second etching stop film 199 may also fill at least a portion of the source/drain contact recess formed between the second interlayer insulating film 196 and the source/drain contact filling film 180b.

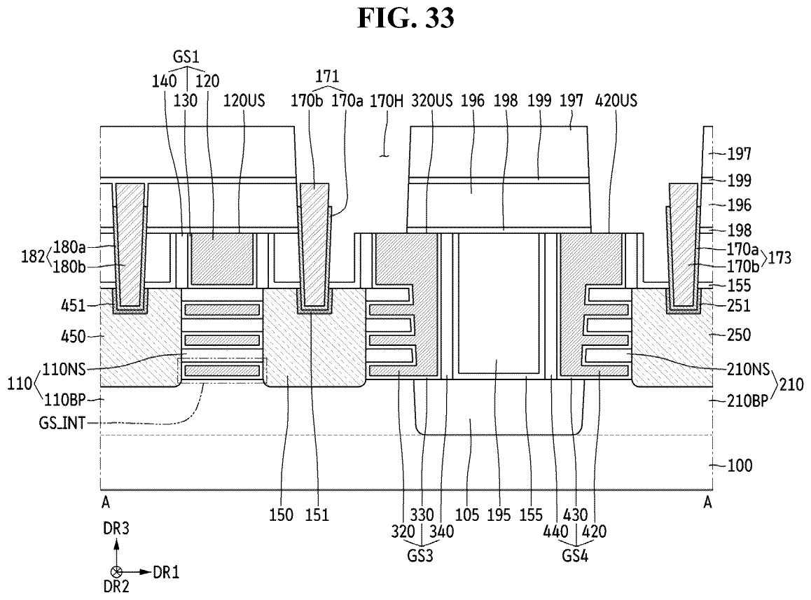

Referring to FIG. 33, node contact holes 170H may be formed in the second interlayer insulating film 196 and the third interlayer insulating film 197.

The node contact holes 170H may extend between the first bridge contact 171 and the third gate electrode 320. The node contact holes 170H may expose the upper surface of the third gate electrode 320 and the upper surface of the bridge contact filling film 170b of the first bridge contact 171.

The node contact holes 170H may extend between the third bridge contact 173 and the fourth gate electrode 420. The node contact holes 170H may expose the upper surface of the fourth gate electrode 420 and the upper surface of the bridge contact filling film 170b of the third bridge contact 173.

In a cross-sectional view, the node contact holes 170H may not expose the first interlayer insulating film 195 formed between the first bridge contact 171 and the first gate electrode 120.

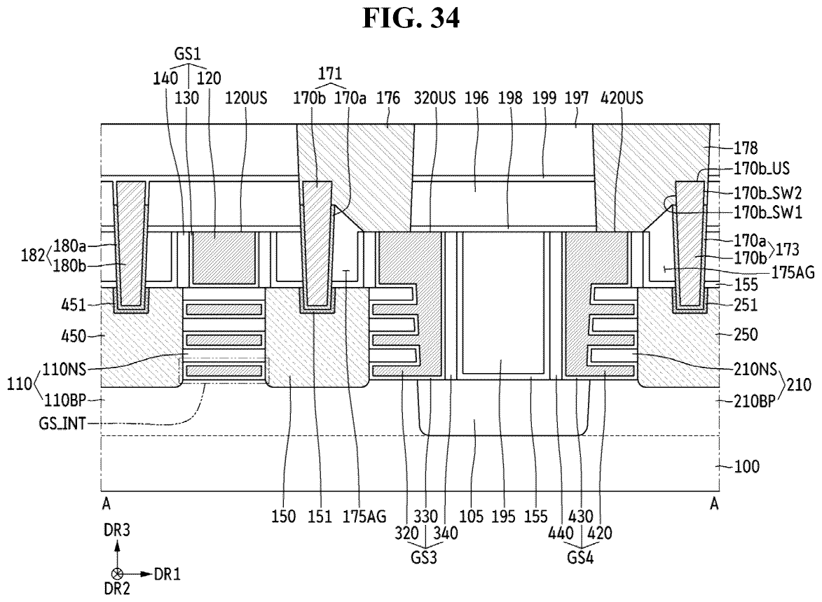

Referring to FIGS. 33 and 34, a first node contact 176 and a third node contact 178 may be formed in the node contact holes 170H.

While forming the first node contact 176 and the third node contact 178, node air gaps 175AG may also be formed in the node contact holes 170H. The node air gaps 175AG may be formed as the first node contact 176 and the third node contact 178 are formed in the node contact holes 170H.

The first node contact 176 and the third node contact 178 may be formed using, for example, a selective chemical vapor deposition (CVD) process. For example, the selective CVD process may involve selectively growing a second conductive film on a first conductive film.

Non-limiting example embodiments of the disclosure have been described above with reference to the accompanying drawings. Those skilled in the art will appreciate that many variations and modifications may be made to the example embodiments without departing from the spirit and scope of the disclosure. Accordingly, the variations and modifications are included within the scope of the disclosure.

What is claimed is:

1. A semiconductor device comprising:
a first gate electrode extending in a first direction;
a second gate electrode extending in the first direction and spaced apart from the first gate electrode in a second direction that crosses the first direction;
a source/drain pattern between the first gate electrode and the second gate electrode;
a source/drain contact between the first gate electrode and the second gate electrode, the source/drain contact connected to the source/drain pattern;
a node contact connected to the source/drain contact and the first gate electrode; and
a node air gap between the first gate electrode and the source/drain contact,
wherein the node air gap is not between the second gate electrode and the source/drain contact.

2. The semiconductor device of claim 1, wherein
the source/drain contact comprises a contact filling film and a contact barrier film, wherein the contact barrier film is between the contact filling film and the source/drain pattern, and
the node contact contacts an upper surface of the contact filling film and is on a portion of a sidewall of the contact filling film.

3. The semiconductor device of claim 2, wherein the node contact contacts the portion of the sidewall of the contact filling film.

4. The semiconductor device of claim 2, further comprising:
a contact liner on a sidewall of the source/drain contact, the contact liner comprising an insulating material.

5. The semiconductor device of claim 2, further comprising:
a contact air gap on the sidewall of the contact filling film,
wherein the contact air gap is between the second gate electrode and the contact filling film, and
a thickness of the contact barrier film, in the second direction, on the sidewall of the contact filling film is equal to or greater than a width of the contact air gap in the second direction.

6. The semiconductor device of claim 1, further comprising:
a first etching stop film and a first interlayer insulating film sequentially disposed on the first gate electrode and the second gate electrode,
wherein the first etching stop film extends along an upper surface of the first gate electrode and an upper surface of the second gate electrode.

7. The semiconductor device of claim 6, wherein
the source/drain contact penetrates the first etching stop film, and
a portion of the source/drain contact is within the first interlayer insulating film.

8. The semiconductor device of claim 6, further comprising:
a second etching stop film and a second interlayer insulating film sequentially disposed on the first interlayer insulating film,
wherein the node contact penetrates the first etching stop film and the second etching stop film.

9. The semiconductor device of claim 1, wherein the node contact comprises a single conductive film structure.

10. The semiconductor device of claim 1, wherein the node contact is not connected to the second gate electrode.

11. A semiconductor device comprising:
a first gate electrode extending in a first direction;
a second gate electrode extending in the first direction and spaced apart from the first gate electrode in a second direction that crosses the first direction;
a source/drain pattern between the first gate electrode and the second gate electrode;
a source/drain contact between the first gate electrode and the second gate electrode, the source/drain contact connected to the source/drain pattern, and comprising a contact barrier film and a contact filling film, wherein the contact barrier film is between the contact filling film and the source/drain pattern;
a node contact connected to the source/drain contact and the first gate electrode, wherein the node contact is in contact with a sidewall of the contact filling film and an upper surface of the contact filling film; and
a node air gap between the first gate electrode and the source/drain contact.

12. The semiconductor device of claim 11, further comprising:
a first etching stop film, an interlayer insulating film, and a second etching stop film sequentially disposed on the first gate electrode and the second gate electrode,
wherein the first etching stop film extends along an upper surface of the first gate electrode and an upper surface of the second gate electrode,
wherein the source/drain contact penetrates the first etching stop film, and
wherein the node contact penetrates the first etching stop film and the second etching stop film.

13. The semiconductor device of claim 12, wherein
the contact barrier film comprises, in a cross-sectional view of the semiconductor device, a first uppermost surface and a second uppermost surface that are lower than the upper surface of the contact filling film,
the first uppermost surface of the contact barrier film is between the contact filling film and the first gate electrode,
the second uppermost surface of the contact barrier film is between the contact filling film and the second gate electrode, and
the first uppermost surface of the contact barrier film contacts the node contact.

14. The semiconductor device of claim 13, wherein the second uppermost surface of the contact barrier film contacts the first etching stop film.

15. The semiconductor device of claim 12, further comprising:
a contact air gap on the sidewall of the contact filling film,
wherein the contact air gap is between the second gate electrode and the contact filling film, and
wherein a thickness of the contact barrier film, in the second direction, on the sidewall of the contact filling film is equal to or greater than a width of the contact air gap in the second direction.

16. The semiconductor device of claim 11, wherein the node air gap is not between the second gate electrode and the source/drain contact.

17. The semiconductor device of claim 11, wherein the node contact comprises a single conductive film structure.

18. A semiconductor device comprising:
a first active pattern extending in a first direction;
a second active pattern extending in the first direction, wherein the first active pattern and the second active pattern are spaced apart from each other in a second direction that crosses the first direction;
a first gate electrode extending in the second direction, wherein the first gate electrode is on the first active pattern and the second active pattern;
a second gate electrode extending in the second direction, wherein the second gate electrode is on the first active pattern, and the second gate electrode is spaced apart from the first gate electrode in the first direction;
a third gate electrode extending in the second direction, wherein the third gate electrode is on the second active pattern, spaced apart from the first gate electrode in the second direction, and overlaps with the second gate electrode in the second direction;
a first source/drain contact between the first gate electrode and the second gate electrode and between the first gate electrode and the third gate electrode;
a second source/drain contact spaced apart from the first source/drain contact in the first direction, wherein the second source/drain contact is on the second active pattern;
a node contact on the first source/drain contact, wherein the node contact comprises a single conductive film structure, and the node contact connects the first source/drain contact and the third gate electrode; and
a node air gap between the third gate electrode and the first source/drain contact,
wherein the node air gap is not disposed between the first gate electrode and the first source/drain contact.

19. The semiconductor device of claim 18, wherein the node air gap does not extend between the second gate electrode and the first source/drain contact.

20. The semiconductor device of claim 18, wherein
the first source/drain contact comprises a contact barrier film and a contact filling film on the contact barrier film, and
the node contact contacts an upper surface of the contact filling film and a portion of a sidewall of the contact filling film.
